(19) United States
(12) Patent Application Publication
(10) Pub. No.: US 2026/0302735 A1
(43) Pub. Date: Oct. 1, 2026

(54) POWER DISTRIBUTION DEVICE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Yusuke ISAJI, Osaka (JP); Hitoshi TAKEDA, Osaka (JP)

(21) Appl. No.: 19/480,826

(22) PCT Filed: Apr. 24, 2024
(86) PCT No.: PCT/JP2024/016023

§ 371 Date: Nov. 3, 2025

(30) Foreign Application Priority Data
May 8, 2023 (JP) 2023-076877

(51) Int. Cl. H02B 1/20; B60L 50/60; B60R 13/08; B60R 16/023; B60R 16/033; G01R 31/382; H01M 10/42; H01M 50/249

(52) U.S. Cl. CPC H02B 1/20; B60R 16/0238; B60R 16/033; G01R 31/382; H01M 10/425; H01M 50/249; B60L 50/60; B60R 13/0869; H01M 2220/20

(57) ABSTRACT

Disclosed is a highly versatile power distribution device which can be easily modified in accordance with the number of battery packs to be mounted. A power distribution device 10 includes a relay 14, a current sensor 16, and a basic circuit 18 to which the relay 14 and the current sensor 16 are connected. The basic circuit 18 comprises: basic circuit units 20 having an input part 24 connected to the terminal part 22 of the battery pack 12, a first output part 26, and a second output part 28; a branch input part 30 connected to at least one of the first output part 26 and the second output part 28 of the basic circuit units 20; and a branch circuit unit 36 having a plurality of branch output parts 34 each connected to the branch input part 30 via a fuse 32. There are as many basic circuit units 20 as the number of battery packs 12 to be mounted. One first output part 26 of a plurality of the basic circuit units 20 arranged adjacently to each other is connected to the other second output part 28 of the plurality of basic circuit units 20, and the plurality of battery packs 12 are conductively connected.

### TECHNICAL FIELD

The present disclosure relates to a power distribution device that is connected to a battery pack.

### BACKGROUND

Patent Document 1 shows a structure in which a junction box that serves as a power distribution device is stored in the casing of a battery pack installed in a vehicle, and power from the battery pack is distributed to vehicle loads via the power distribution device.

### PRIOR ART DOCUMENT

### Patent Document

Patent Document 1: JP 2012-243449 A

### SUMMARY OF THE INVENTION

### Problems to be Solved

Incidentally, given that the battery capacity required for a vehicle differs depending on the vehicle model, and the number of battery packs installed in a vehicle increases or decreases depending on the vehicle model, the power distribution device that is connected to the battery packs needs to be specifically designed according to the number of battery packs. As a result, there is the inherent problem of different power distribution devices being required for different vehicles and inevitable cost increases.

In view of this, a highly versatile power distribution device that is readily modifiable according to the number of battery packs to be installed is disclosed.

### Means to Solve the Problem

A power distribution device of the present disclosure is provided with a basic circuit unit including a relay, a current sensor, and a basic circuit to which the relay and the current sensor are connected, the basic circuit having an input part connected to a terminal of a battery pack, a first output part, and a second output part, and with a branch circuit unit including a branch input part connected to at least one of the first output part and the second output part of the basic circuit unit, and a plurality of branch output parts each connected to the branch input part via a fuse, the basic circuit unit being disposed corresponding in number to how many of the battery pack are to be installed in a vehicle, and, in a case where a plurality of the basic circuit unit are employed corresponding to a plurality of the battery pack, the first output part of one of the basic circuit units adjacently disposed is coupled to the second output part of the other basic circuit unit adjacently disposed and the battery packs are conductively connected.

### Effect of the Invention

According to the present disclosure, a highly versatile power distribution device that is readily modifiable according to the number of battery packs to be installed can be provided.

### BRIEF DESCRIPTION OF THE DRAWINGS

FIG. 1 is a perspective view showing a power distribution device according to Embodiment 1 with four battery packs attached.

FIG. 2 is a perspective view showing the power distribution device shown in FIG. 1 with a cover removed.

FIG. 3 is a plan view of the power distribution device shown in FIG. 2.

FIG. 4 is a perspective view showing the power distribution device shown in FIG. 2 with main constituent members removed.

FIG. 5 is a perspective view showing the power distribution device shown in FIG. 2 with members constituting electrical circuits removed.

FIG. 6 is a perspective view showing the power distribution device shown in FIG. 2 with members supporting the electrical circuits removed.

FIG. 7 is a perspective view showing a first basic circuit unit which is one of the basic circuit units constituting the power distribution device shown in FIG. 2.

FIG. 8 is a perspective view showing a second basic circuit unit which is another basic circuit unit constituting the power distribution device shown in FIG. 2.

FIG. 9 is a perspective view showing a circuit support body constituting the basic circuit units of the power distribution device shown in FIG. 2 with a current sensor and a relay attached.

FIG. 10 is a front view showing the circuit support body shown in FIG. 9 without the current sensor and the relay attached.

FIG. 11 is a perspective view from above showing a branch circuit unit constituting the power distribution device shown in FIG. 2.

FIG. 12 is a perspective view from below of the branch circuit unit shown in FIG. 11.

FIG. 13 is a circuit diagram for describing an electrical configuration of the power distribution device shown in FIG. 2.

FIG. 14 is a perspective view showing a power distribution device according to Embodiment 1 with two battery packs attached.

FIG. 15 is a perspective view showing the power distribution device shown in FIG. 14 with a cover removed.

FIG. 16 is a plan view of the power distribution device shown in FIG. 15.

FIG. 17 is a perspective view of the power distribution device shown in FIG. 15 with main constituent members removed.

FIG. 18 is a perspective view showing the power distribution device shown in FIG. 15 with members constituting electrical circuits removed.

FIG. 19 is a perspective view showing the power distribution device shown in FIG. 15 with members supporting the electrical circuits removed.

FIG. 20 is a circuit diagram for describing an electrical configuration of the power distribution device shown in FIG. 15.

### DETAILED DESCRIPTION TO EXECUTE THE INVENTION

### Summary of Embodiments of Disclosure

Initially, modes of the present disclosure will be enumerated and described.
(1) A power distribution device of the present disclosure is a power distribution device provided with a basic circuit unit including a relay, a current sensor, and a basic circuit to which the relay and the current sensor are connected, the basic circuit having an input part connected to a terminal of a battery pack, a first output part, and a second output part, and with a branch circuit unit including a branch input part connected to at least one of the first output part and the second output part of the basic circuit unit, and a plurality of branch output parts each connected to the branch input part via a fuse, the basic circuit unit being disposed corresponding in number to how many of the battery pack are to be installed in a vehicle, and, in a case where a plurality of the basic circuit unit are employed corresponding to a plurality of the battery pack, the first output part of one of the basic circuit units adjacently disposed is coupled to the second output part of the other basic circuit unit adjacently disposed and the battery packs are conductively connected.

According to the power distribution device of the present disclosure, a basic circuit unit including a relay, a current sensor, and a basic circuit (having an input part connected to a battery pack, and first/second output parts) is constituted. This basic circuit unit is disposed corresponding in number to the number of battery packs to be installed in the vehicle, and the input part of the basic circuit unit is connected to a terminal of the battery pack. In the case where a plurality of battery packs are installed in the vehicle, the battery packs can be conductively connected, by coupling the first output part of one of the basic circuit units adjacently disposed to the second output part of the other basic circuit unit adjacently disposed. Furthermore, a branch circuit unit is connected to at least one of the first output part and the second output part of the basic circuit unit, enabling power from one battery pack or a plurality of coupled battery packs to be distributed to the branch output parts of the branch circuit unit. With a power distribution device having such a structure, the number of basic circuit units need only be increased or decreased corresponding to the number of battery packs to be installed in the vehicle, and, in the case where a plurality of basic circuit units are employed, the number of basic circuit units is changed corresponding to the number of battery packs to be installed by simply coupling the output parts of the basic circuit units. A highly versatile power distribution device that is readily modifiable according to the number of battery packs to be installed can thereby be provided.
(2) In (1) above, preferably the basic circuit unit includes an insulating circuit support body, the current sensor is mounted to a current sensor mounting part provided at one end side of the circuit support body, and the relay is mounted to a relay mounting part provided at the other end side of the circuit support body, and the basic circuit is constituted including a plurality of busbars each provided with one of the input part, the first output part, and the second output part at an end thereof, and is assembled to the circuit support body.

Given that the relay, the current sensor, and the plurality of busbars constituting the basic circuit with which the basic circuit unit is constituted are held by an insulating circuit support body, the ability to handle and hold the basic circuit unit can be improved, and improvement in the operability with which the basic circuit units are coupled can also be achieved. Also, given that the basic circuit is constituted including a plurality of busbars each provided with one of the input part, the first output part, and the second output part at an end thereof, further improvement in versatility can also be achieved, by modifying the shape of the busbars to correspond to the connection configuration (series/parallel) of the battery packs as appropriate.
(3) In (2) above, preferably the power distribution device includes a metal casing accommodating the basic circuit unit and the branch circuit unit, and the busbars connected to the relay have a contact part for heat dissipation that thermally contacts the casing via an insulating member. Among the plurality of busbars constituting the basic circuit, the busbars connected to the relay, which is a heat-generating component, have a contact part for heat dissipation, and the heat dissipation contact part thermally contacts a metal casing that accommodates the basic circuit unit and the branch circuit unit. The heat of the relay can thereby be quickly transferred to the metal casing, and improvement in the heat dissipation of the relay can be achieved in a space-efficient manner.
(4) In (2) or (3) above, preferably the power distribution device further includes an insulating terminal block disposed between the circuit support bodies of the basic circuit units adjacently disposed, and one of the basic circuit units and the other basic circuit unit are held and coupled together in the terminal block. By disposing a terminal block between adjacently disposed basic circuit units, the position of the basic circuit units can be advantageously adjusted in order to enable connection to a plurality of battery packs. Furthermore, by using the terminal block to hold the basic circuit units that are to be coupled together, coupling of the basic circuit units can be stably performed with good operability. Furthermore, it also becomes possible to utilize the space of the terminal block to modify the orientation of output parts of the busbars to facilitate coupling, and improvement in the design freedom of the busbars and in assembly operability can also be achieved.

### Detailed Description of Embodiments of Disclosure

A specific example of a power distribution device of the present disclosure will be described below with reference to the drawings. Note that the present disclosure is not limited to these illustrative examples and is indicated by the claims, and all changes that come within the meaning and range of equivalency of the claims are intended to be embraced therein.

### Embodiment 1

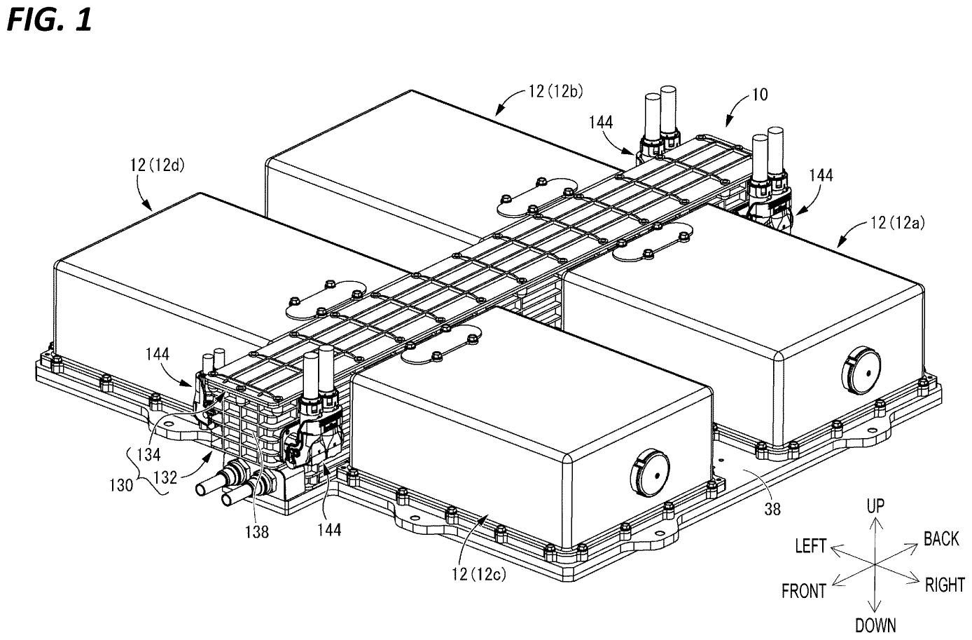

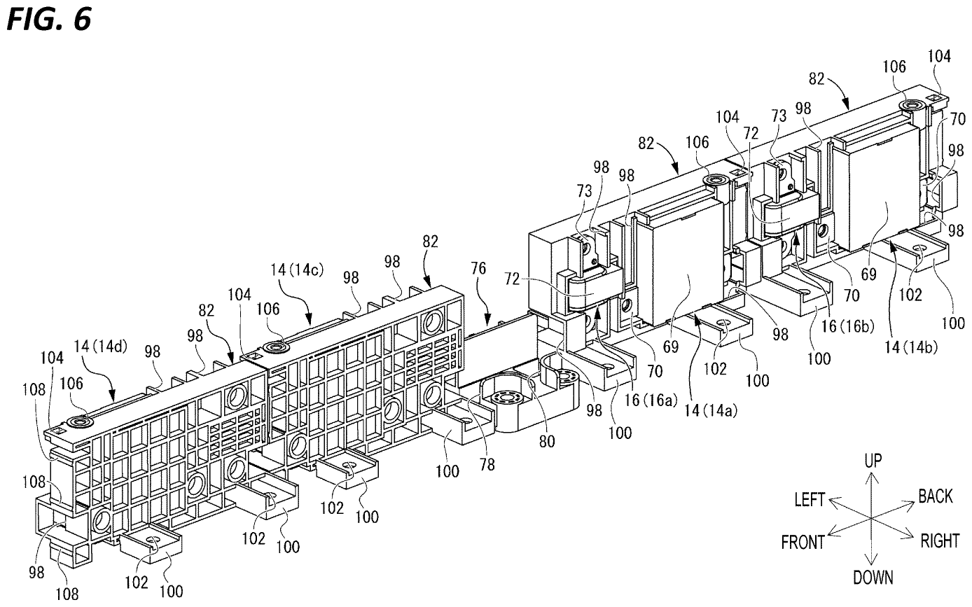

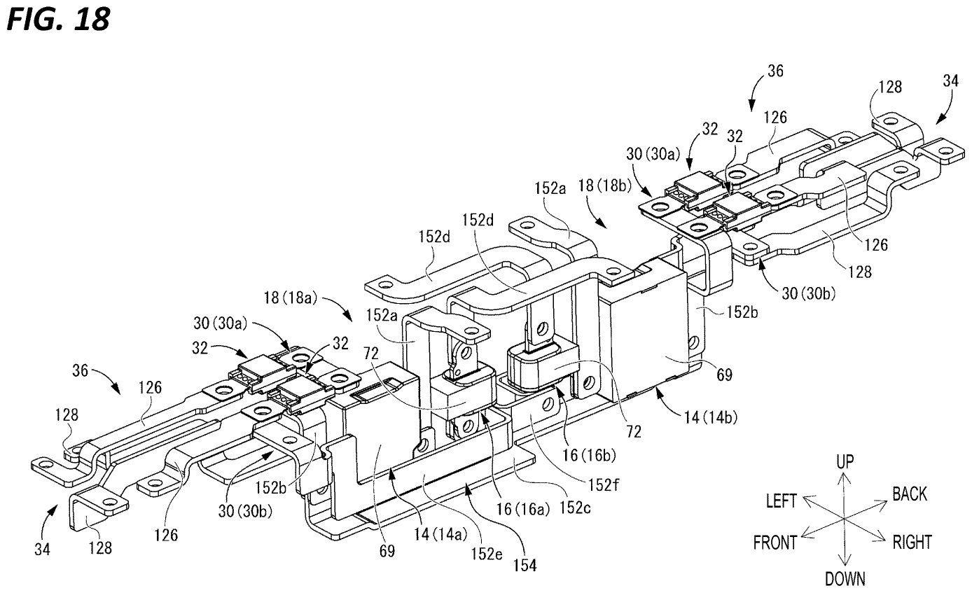

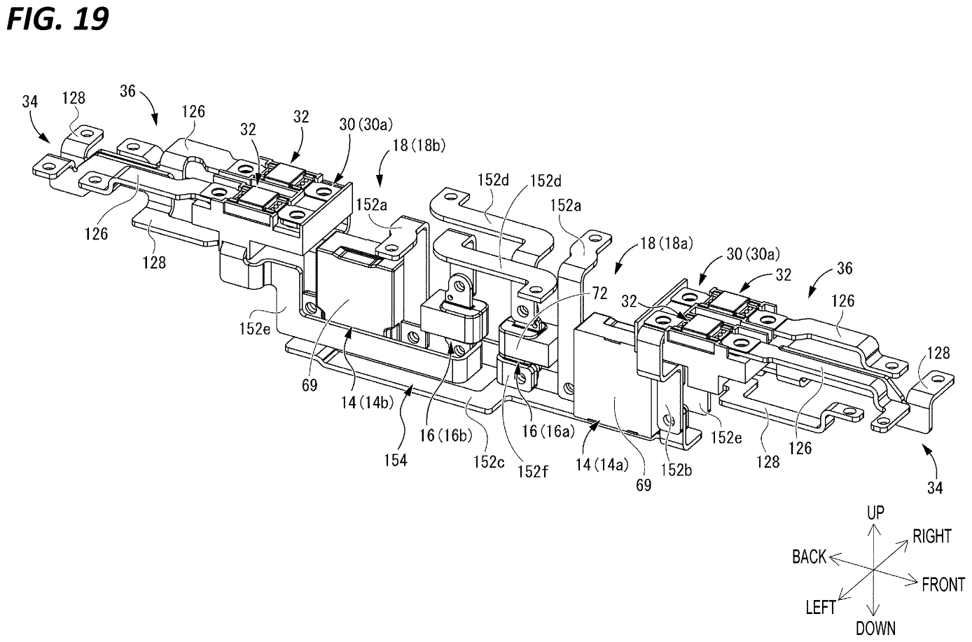

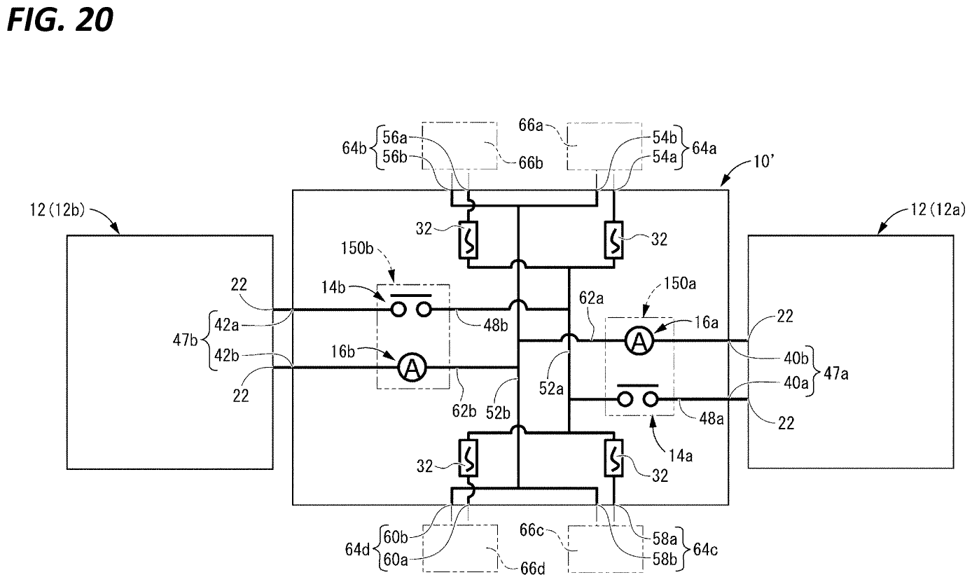

Hereinafter, power distribution devices 10 and 10′ of Embodiment 1 of the present disclosure will be described using FIG. 1 to FIG. 20. The power distribution devices 10 and 10′ of Embodiment 1 are installed in an electric vehicle or a hybrid vehicle, for example, and are connected to a plurality of battery packs 12 and distribute power from the battery packs 12 to a plurality of loads (e.g., auxiliary equipment, etc.; first to fourth loads 66a to 66d described below). Note that while the power distribution devices 10 and 10′ can be disposed in any orientation, hereinafter, the up-down direction, left-right direction and front-back direction will be described as the up-down direction, left-right direction and front-back direction indicated in the diagrams. Also, there are cases where reference signs are given to only some of a plurality of members that are the same, and reference signs are not given to the other members.

### Power Distribution Devices 10 and 10′

The power distribution devices 10 and 10′ are provided with a basic circuit unit 20 that includes a relay 14 (first to fourth relays 14a to 14d described below), a current sensor 16 (first to fourth current sensors 16a to 16d) and a basic circuit 18 to which the relay 14 and the current sensor 16 are connected, or with a later-described basic circuit unit 150. The basic circuit 18 has an input part 24 that is connected to a terminal 22 of the battery pack 12, a first output part 26, and a second output part 28. Also, the power distribution devices 10 and 10′ are provided with a branch circuit unit 36 including a branch input part 30 connected to at least one of the first output part 26 and the second output part 28 of the basic circuit unit 20, and a plurality of branch output parts 34 each connected the branch input part 30 via a fuse 32.

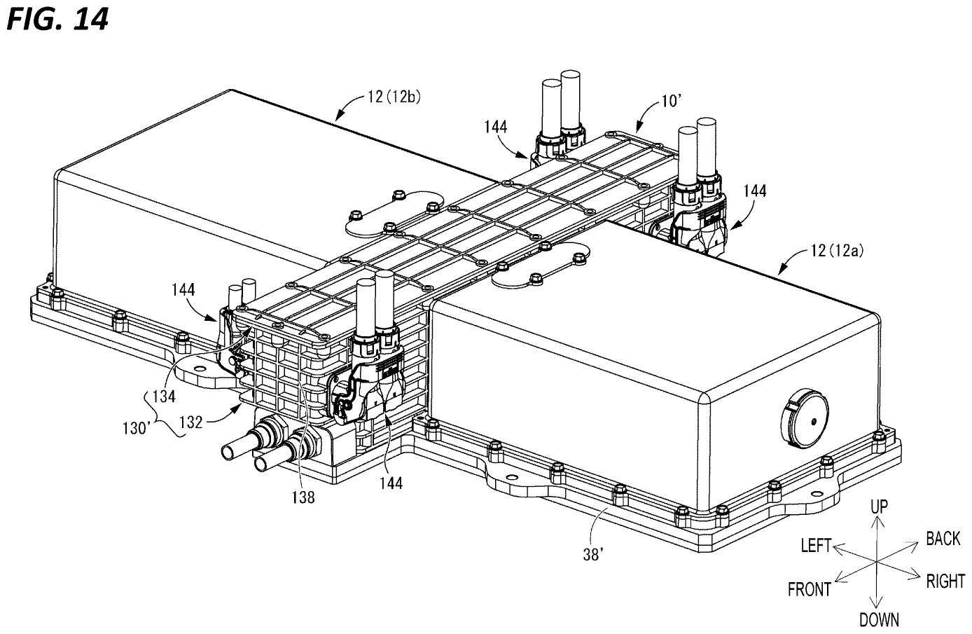

In the power distribution devices 10 and 10′ of the present disclosure, it is possible to change the number of basic circuit units 20 according to the number of battery packs 12. FIG. 1 to FIG. 13 show an example in which four battery packs 12 (first battery pack 12a to fourth battery pack 12d) are connected to the power distribution device 10, and FIG. 14 to FIG. 20 show an example in which two battery packs 12 (first and second battery packs 12a and 12b) are connected to the power distribution device 10′. Note that, as shown in FIG. 1, as the battery packs 12 connected to the power distribution device 10, the battery pack 12 on the back right is given as a first battery pack 12a, the battery pack 12 on the back left is given as a second battery pack 12b, the battery pack 12 on the front right is given as a third battery pack 12c, and the battery pack 12 on the front left is given as a fourth battery pack 12d. Also, as shown in FIG. 14, as the battery packs 12 connected to the power distribution device 10′, the battery pack 12 on the right is given as a first battery pack 12a, and the battery pack 12 on the left is given as a second battery pack 12b. Note that, given that known battery packs are employed as the battery packs 12, description of the internal structure thereof is omitted.

That is, in the power distribution device 10 shown in FIG. 1 and the like, the battery packs 12a to 12d are provided on both left and right sides with the power distribution device 10 interposed therebetween, and are provided with a predetermined distance therebetween in the front-back direction. The power distribution device 10 and the battery packs 12a to 12d are placed on a substantially rectangular flat plate-shaped support plate 38 and fixed thereto with bolts, for example. Similarly, in the power distribution device 10′ shown in FIG. 14 and the like, the battery packs 12a and 12b are provided on both left and right sides with the power distribution device 10′ interposed therebetween. The power distribution devices 10′ and the battery packs 12a and 12b are placed on a substantially rectangular flat plate-shaped support plate 38′ and fixed thereto with bolts, for example.

In the power distribution device 10, four basic circuit units 20 (first to fourth basic circuit units 20a to 20d) are provided corresponding to the four battery packs 12 (first to fourth battery packs 12a to 12d). For convenience, the basic circuit units 20 provided in the power distribution device 10 are, in order from the front, given as a fourth basic circuit unit 20d, a third basic circuit unit 20c, a first basic circuit unit 20a, and a second basic circuit unit 20b. Note that the relays 14 (first to fourth relays 14a to 14d) and the current sensors 16a (first to fourth current sensor 16a to 16b) respectively provided in the basic circuit units 20a to 20d are not necessarily connected to the corresponding battery packs 12 (first to fourth battery packs 12a to 12d).

### Electrical Configuration of Power Distribution Device 10

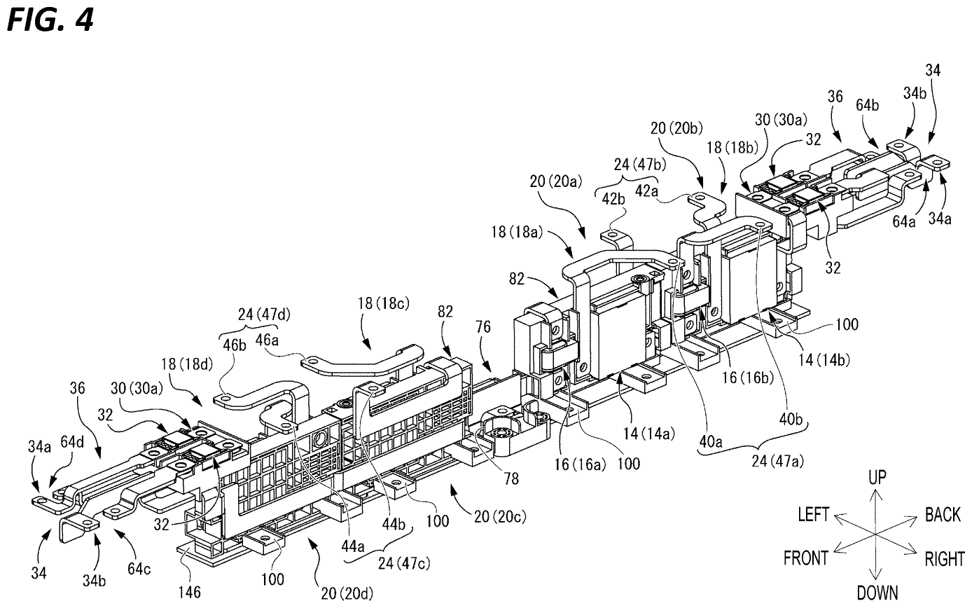

First, the electrical configuration of the power distribution device 10 will be described by showing FIGS. 4 and 5, FIG. 13, and the like. The power distribution device 10 is provided with a first cathode-side input part 40a to which the cathode side of the first battery pack 12a is connected, and a first anode-side input part 40b to which the anode side of the first battery pack 12b is connected. Similarly, the power distribution device 10 is provided with second to fourth cathode-side input parts 42a, 44a, and 46a to which the cathode sides of the second to fourth battery packs 12b to 12d are connected, and second to fourth anode-side input parts 42b, 44b, and 46b to which the anode sides of the second to fourth battery packs 12b to 12d are connected. A first input part 47a is constituted by the first cathode-side and anode-side input parts 40a and 40b, a second input part 47b is constituted by the second cathode-side and anode-side input parts 42a and 42b, a third input part 47c is constituted by the third cathode-side and anode-side input parts 44a and 44b, and a fourth input part 47d is constituted by the fourth cathode-side and anode-side input parts 46a and 46b.

As mentioned above, the power distribution device 10 is provided with four basic circuit units 20 (first to fourth basic circuit unit 20a to 20d), and thus has four relays 14 (first to fourth relays 14a to 14d) and four current sensors 16 (first to fourth current sensors 16a to 16d). First to fourth cathode-side lines 48a to 48d respectively extend from the cathode-side input parts 40a, 42a, 44a, 46a, and the first to fourth relays 14a to 14d are respectively connected of the cathode-side lines 48a to 48d. Also, downstream of the relays 14a to 14d, the cathode-side lines 48a to 48d are connected in parallel to a cathode-side connecting line 52a. This cathode-side connecting line 52a is divided into four downstream and constituted as first to fourth cathode-side branch output parts 54a, 56a, 58a, and 60a via the aforementioned fuses 32.

Similarly, first to fourth anode-side lines 62a to 62d respectively extend from the anode-side input parts 40b, 42b, 44b, and 46b. The second current sensor 16b of the second basic circuit unit 20b is connected to the first anode-side line 62a, and the first current sensor 16a of the first basic circuit unit 20a is connected to the second anode-side line 62b. The fourth current sensor 16d of the fourth basic circuit unit 62d is connected to the third anode-side line 62c, and the third current sensor 16c of the third basic circuit unit 62c is connected to the fourth anode-side line 62d. Also, downstream of the current sensors 16a to 16d, the anode-side lines 62a to 62d are connected in parallel to an anode-side connecting line 52b. This anode-side connecting line 52b is divided into four downstream and constituted as first to fourth anode-side branch output parts 54b, 56b, 58b, and 60b.

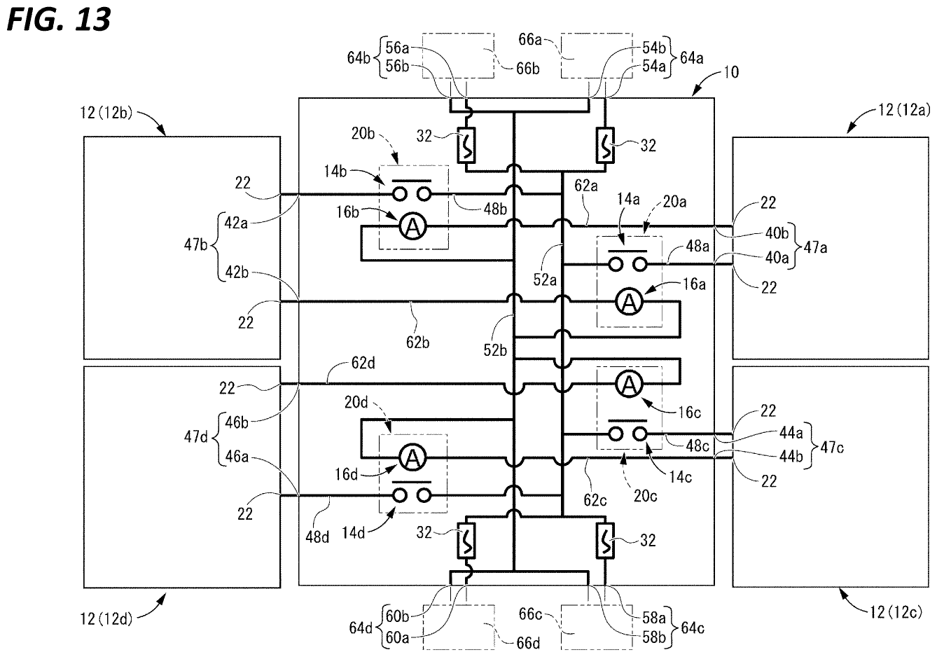

A first load-side branch output part 64a is constituted by the first cathode-side and anode-side branch output parts 54a and 54b, and a first load 66a is connected to the first load-side branch output part 64a, as shown by a two-dot chain line in FIG. 13. Similarly, a second load-side branch output part 64b is constituted by the second cathode-side and anode-side branch output parts 56a and 56b and a second load 66b is connected thereto, a third load-side branch output part 64c is constituted by the third cathode-side and anode-side branch output parts 58a and 58b and a third load 66c is connected thereto, and a fourth load-side branch output part 64d is constituted by the fourth cathode-side and anode-side branch output parts 60a and 60b and a fourth load 66d is connected thereto. With such an electrical circuit configuration, in the power distribution device 10 shown in FIG. 1 and the like, the four battery packs 12a to 12d are connected in parallel, and power obtained from the battery packs 12a to 12d is distributed to the first to fourth loads 66a to 66d.

Although the voltage magnitude of the battery packs 12a to 12d connected to the power distribution device 10 is not limited, the battery packs 12a to 12d can be regarded as known 48 V batteries, for example. Also, the relays 14a to 14d can be regarded as known mechanical relays. As aforementioned, the power distribution device 10 is provided with, in order from the front, the fourth basic circuit unit 20d, the third basic circuit unit 20c, the first basic circuit unit 20a, and the second basic circuit unit 20b, and thus the relays 14a to 14d provided in the power distribution device 10 are, in order from the front, the fourth relay 14d, the third relay 14c, the first relay 14a, and the second relay 14b.

### Busbars 68

Here, in the above electrical circuits of the power distribution device 10, the first to fourth cathode-side lines 48a to 48d, the first to fourth anode-side lines 62a to 62d, the cathode-side and anode-side connecting lines 52a and 52b, and the like need only be constituted by conductive members. The above may be constituted by electrical wires and the like, for example, and, in Embodiment 1, are constituted by a plurality of busbars 68 (busbars 68a to 68j below). The connection between the busbars 68 themselves, between the busbars 68 and the relays 14a to 14d, and between the busbars 68 and the current sensors 16a to 16d can be obtained by, for example, inserting and fastening bolts (not shown) in bolt insertion holes provided in the ends of the busbars 68.

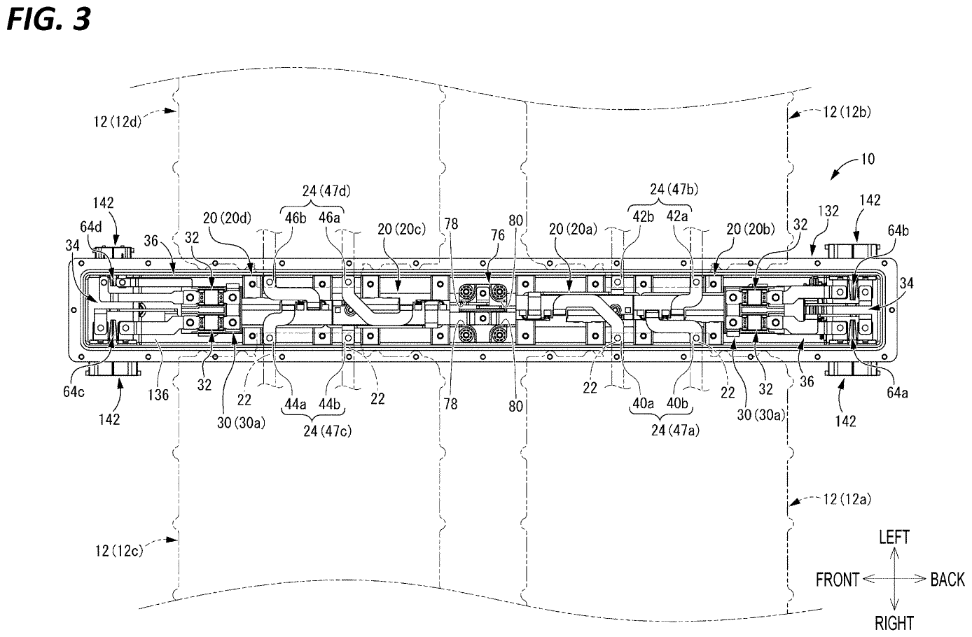

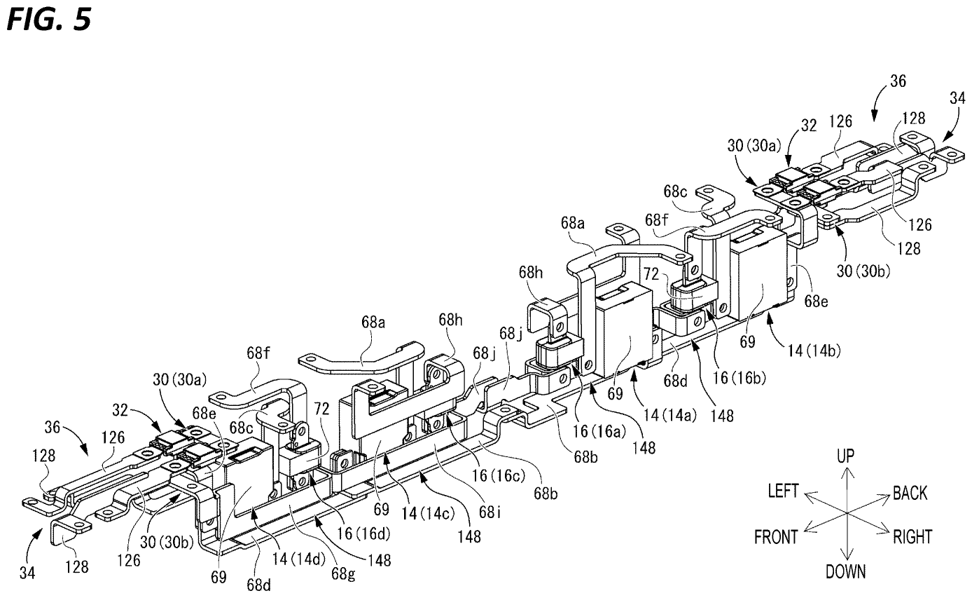

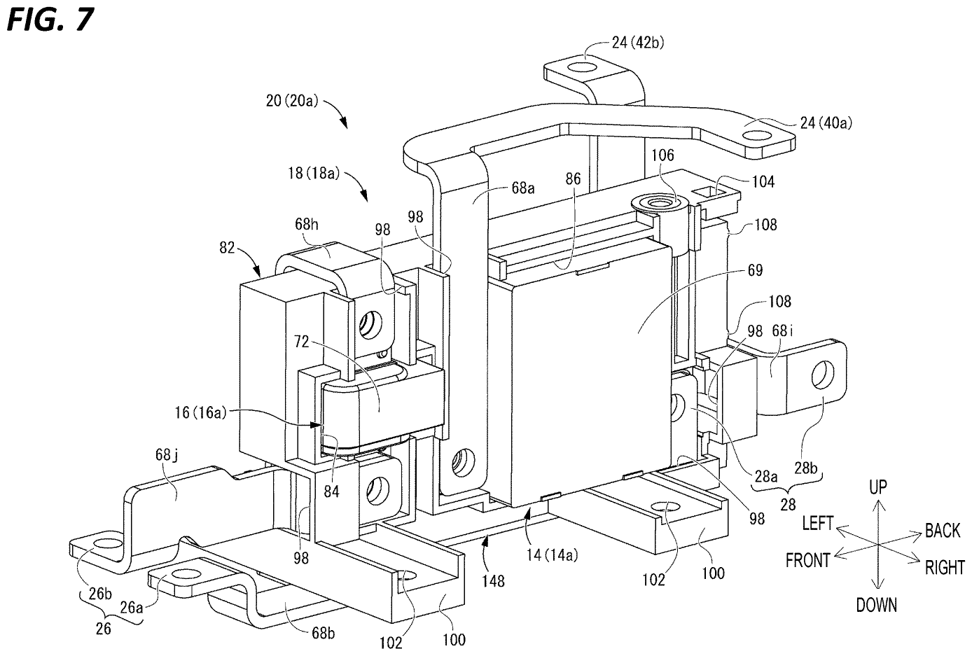

As shown in FIG. 3 and FIG. 5, the power distribution device 10 includes the busbar 68a that is provided with the first cathode-side input part 40a connected to the first battery pack 12a and is electrically connected to the first relay 14a. In other words, the first cathode-side input part 40a is constituted by one end of the busbar 68a, and the connecting part to the first relay 14a is constituted by the other end of the busbar 68a. As shown in FIG. 7, the first basic circuit unit 20a, which is one of the basic circuit units 20, includes the busbar 68a, and the first cathode-side input part 40a serving as the input part 24 connected to the terminal 22 of the first battery pack 12a is constituted by the one end of the busbar 68a. In the first basic circuit unit 20a, the one end (first cathode-side input part 40a) of the busbar 68a protrudes rightward toward the first relay 14a side. The other end of the busbar 68a is electrically connected to the first relay 14a, by being overlapped with and bolt-fastened to a terminal 70 that protrudes from a main body 69 of the first relay 14a.

Also, the busbar 68b is connected to the downstream side of the first relay 14a. That is, the busbar 68b is provided in the first basic circuit unit 20a, and is a busbar that constitutes the cathode-side connecting line 52a or is connected to the cathode-side connecting line 52a. One end (front end) of the busbar 68b constitutes the first output part 26 (positive-side first output part 26a) of the first basic circuit unit 20a, and the other end (rear end) of the busbar 68b constitutes the second output part 28 (positive-side second output part 28a) of the first basic circuit unit 20a. The other end (positive-side second output part 28a) of the busbar 68b is overlapped with a terminal 70 that protrudes from the main body 69 of the first relay 14a. The busbar 68b extends in the front-back direction as a whole downward of the first basic circuit unit 20a, with the one end (positive-side first output part 26a) of the busbar 68b protruding forward, and the other end (positive-side second output part 26b) of the busbar 68b being exposed to the outside (right side) in the rear portion of the first basic circuit unit 20a.

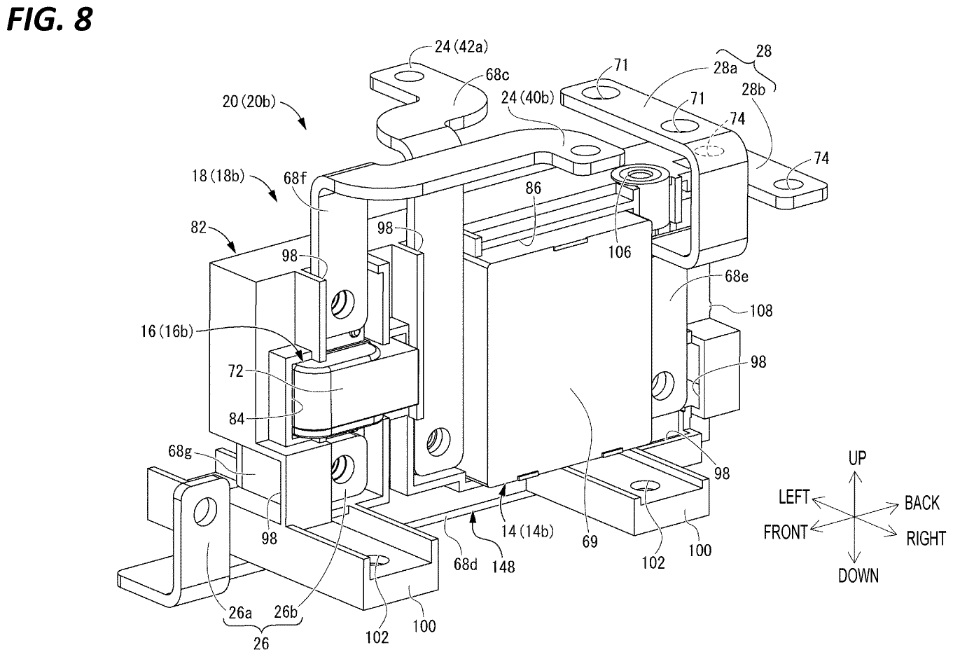

Furthermore, as shown in FIG. 3 and FIG. 5, the power distribution device 10 includes the busbar 68c that is provided with the second cathode-side input part 42a connected to the second battery pack 12b and is electrically connected to the second relay 14b. In other words, the second cathode-side input part 42a is constituted by one end of the busbar 68c, and the connecting part to the second relay 14b is constituted by the other end of the busbar 68c. As shown in FIG. 8, the second basic circuit unit 20b, which is another one of the basic circuit units 20, includes the busbar 68c, and the second cathode-side input part 42a serving as the input part 24 connected to the terminal 22 of the second battery pack 12b is constituted by the one end of the busbar 68c. In the second basic circuit unit 20b, the one end (second cathode-side input part 42a) of the busbar 68c protrudes leftward toward the second relay 14b side. The other end of the busbar 68c is electrically connected to the second relay 14b, by being overlapped with and bolt-fastened to a terminal 70 that protrudes from the main body 69 of the second relay 14b.

The busbar 68d is connected to the downstream side of the second relay 14b. That is, the busbar 68d is provided in the second basic circuit unit 20b, and is a busbar that constitutes the cathode-side connecting line 52a or is connected to the cathode-side connecting line 52a. One end (front end) of the busbar 68d constitutes the first output part 26 (positive-side first output part 26a) of the second basic circuit unit 20b, and one end of the busbar 68e is connected to the other end (rear end) of the busbar 68d. The second output part 28 (positive-side second output part 28a) of the second basic circuit unit 20b is constituted by the other end of the busbar 68e. The other end of the busbar 68d and the one end of the busbar 68e are overlapped with a terminal 70 that protrudes from the main body 69 of the second relay 14b and can be electrically connected by bolt-fastening.

The busbar 68d extends in the front-back direction as a whole downward of the second basic circuit unit 20b, with the one end (positive-side first output part 26a) of the busbar 68d protruding forward. The busbar 68e extends in the up-down direction as a whole, with the positive-side second output part 28a being constituted by the other end (upper end) of the busbar 68e. In the busbar 68e, two bolt insertion holes 71 and 71 are provided spaced from each other in the positive-side second output part 28a.

Also, as shown in FIG. 3 and FIG. 5, the power distribution device 10 includes the busbar 68f that is provided with the first anode-side input part 40b connected to the first battery pack 12a and is electrically connected to the second current sensor 16b. In other words, the first anode-side input part 40b is constituted by one end of the busbar 68f, and the connecting part to the second current sensor 16b is constituted by the other end of the busbar 68f. As shown in FIG. 8, the second basic circuit unit 20b includes the busbar 68f, and the first anode-side input part 40b serving as the input part 24 connected to the terminal 22 of the first battery pack 12a is constituted by the one end of the busbar 68f. In the second basic circuit unit 20b, the one end (first anode-side input part 40b) of the busbar 68f protrudes rightward toward the first relay 14a side. The other end of the busbar 68f is electrically connected to the second current sensor 16b, by being overlapped with and bolt-fastened to a terminal 73 that protrudes from a main body 72 of the second current sensor 16b.

The busbar 68g is connected to the downstream side of the second current sensor 16b. That is, the busbar 68g is provided in the second basic circuit unit 20b, and is a busbar that constitutes the anode-side connecting line 52b or is connected to the anode-side connecting line 52b. One end (front end) of the busbar 68g constitutes the first output part 26 (negative-side first output part 26b) of the second basic circuit unit 20b, and the other end (rear end) of the busbar 68g constitutes the second output part 28 (negative-side second output part 28b) of the second basic circuit unit 20b. The one end (negative-side first output part 26b) of the busbar 68g is overlapped with a terminal 73 that protrudes from the main body 72 of the second current sensor 16b.

The busbar 68g extends in the front-back direction as a whole on the left surface of the second basic circuit unit 20b, with the one end (negative-side first output part 26b) of the busbar 68g being exposed to the outside (right side) in the front portion of the second basic circuit unit 20b, and the other end (negative-side second output part 28b) of the busbar 68g protruding rearward. In the busbar 68g, two bolt insertion holes 74 and 74 are provided spaced from each other in the negative-side second output part 28b.

Furthermore, as shown in FIG. 3 and FIG. 5, the power distribution device 10 includes the busbar 68h that is provided with the second anode-side input part 42b connected to the second battery pack 12b and is electrically connected to the first current sensor 16a. In other words, the second anode-side input part 42b is constituted by one end of the busbar 68h, and the connecting part to the first current sensor 16a is constituted by the other end of the busbar 68h. As shown in FIG. 7, the first basic circuit unit 20a includes the busbar 68h, and the second anode-side input part 42b serving as the input part 24 connected to the terminal 22 of the second battery pack 12b is constituted by the one end of the busbar 68h. In the first basic circuit unit 20a, the one end (second anode-side input part 42b) of the busbar 68h protrudes leftward toward the second relay 14b side. The other end of the busbar 68h is electrically connected to the first current sensor 16a, by being overlapped with and bolt-fastened to a terminal 73 that protrudes from the main body 72 of the first current sensor 16a. The busbar 68h extends in the front-back direction as a whole on the left surface of the first basic circuit unit 20a.

The busbar 68i is connected to the downstream side of the first current sensor 16a. That is, the busbar 68i is provided in the first basic circuit unit 20a, and is a busbar that constitutes the anode-side connecting line 52b or is connected to the anode-side connecting line 52b. The other end of the busbar 68j is connected to one end (front end) of the busbar 68i. The first output part 26 (negative-side first output part 26b) of the first basic circuit unit 20a is constituted by one end of this busbar 68j. Also, the second output part 28 (negative-side second output part 28b) of the first basic circuit unit 20a is constituted by the other end of the busbar 68i. The one end of the busbar 68i and the other end of the busbar 68j are overlapped with a terminal 73 that protrudes from the main body 72 of the first current sensor 16a.

The busbar 68i extends in the front-back direction as a whole in the first basic circuit unit 20a, with the other end (negative-side second output part 28b) of the busbar 68i protruding rearward. The busbar 68j extends in the front-back direction as a whole, with the one end (negative-side first output part 26a) of the busbar 68j protruding forward.

### Basic Circuit Units 20 (First to Fourth Basic Circuit Units 20a to 20d)

From the above, as shown in FIG. 7, the first basic circuit unit 20a is provided with the first relay 14a and the first current sensor 16a, the busbars 68a and 68b connected to the first relay 14a, and the busbars 68h, 68i, and 68j connected to the first current sensor 16a. Also, as shown in FIG. 8, the second basic circuit unit 20b is provided with the second relay 14b and the second current sensor 16b, the busbars 68c, 68d, and 68e connected to the second relay 14b, and the busbars 68f and 68g connected to the second current sensor 16b.

As shown in FIG. 3 to FIG. 5, the first basic circuit unit 20a and second basic circuit unit 20b are connected in the front-back direction. That is, the front portion of the second basic circuit unit 20b is connected to the rear portion of the first basic circuit unit 20a. Specifically, the positive-side first output part 26a protruding forward in the front portion of the second basic circuit unit 20b is overlapped with and electrically connected by bolt-fastening to the positive-side second output part 28a exposed to the outside (right side) in the rear portion of the first basic circuit unit 20a. Similarly, the negative-side first output part 26b exposed to the outside (right side) in the front portion of the second basic circuit unit 20b is overlapped with and electrically connected by bolt-fastening to the negative-side second output part 28b protruding rearward in the rear portion of the first basic circuit unit 20a. In short, the second output part 28 constituted by the positive-side and negative-side second output parts 28a and 28b in the rear portion of the first basic circuit unit 20a and the first output part 26 constituted by the positive-side and negative-side first output parts 26a and 26b in the front portion of the second basic circuit unit 20b are connected to each other.

Also, the third and fourth basic circuit units 20c and 20d respectively have similar configurations to the first and second basic circuit units 20a and 20b. Specifically, the third basic circuit unit 20c has the shape of the first basic circuit unit 20a rotated 180 degrees around a central axis extending in the up-down direction. That is, the third basic circuit unit 20c is provided with the third relay 14c and the third current sensor 16c, the busbars 68a and 68b connected to the third relay 14c, and the busbars 68h, 68i, and 68j connected to the third current sensor 16c. Also, the fourth basic circuit unit 20d has the shape of the second basic circuit unit 20b rotated 180 degrees around a central axis extending in the up-down direction. That is, the fourth basic circuit unit 20d is provided with the fourth relay 14d and the fourth current sensor 16d, the busbars 68c, 68d, and 68e connected to the fourth relay 14d, and the busbars 68f and 68g connected to the fourth current sensor 16d.

Note that, similarly, in the third and fourth basic circuit units 20c and 20d, the output part located forward is the first output part 26, and the output part located rearward is the second output part 28. In short, the second output part 28 of the third basic circuit unit 20c is constituted with the configuration of the first output part 26 of the first basic circuit unit 20a, and the first output part 26 of the third basic circuit unit 20a is constituted with the configuration of the second output part 28 of the first basic circuit unit 20a. Similarly, the second output part 28 of the fourth basic circuit unit 20d is constituted with the configuration of the first output part 26 in the second basic circuit unit 20b, and the first output part 26 of the fourth basic circuit unit 20d is constituted with the configuration of the second output part 28 in the second basic circuit unit 20b.

As shown in FIG. 3 to FIG. 5, the third basic circuit unit 20c and the fourth basic circuit unit 20d are connected in the front-back direction. That is, the front portion of the third basic circuit unit 20c (i.e., rear portion of first basic unit 20a) is connected to the rear portion of the fourth basic unit 20d (i.e., front portion of second basic unit 20b). Given that the connection mode of the third basic circuit unit 20c and the fourth basic circuit unit 20d is similar to the connection mode of the first basic circuit unit 20a and the second basic circuit unit 20b, description thereof is omitted. Also, the rear portion of the third basic circuit unit 20c is connected to the front portion of the first basic circuit unit 20a, in short, in terms of shape, the front portions of first basic circuit units 20a are connected to each other.

Specifically, the positive-side second output part 28a protruding rearward from the third basic circuit unit 20c and the positive-side first output part 26a protruding forward from the first basic circuit unit 20a are overlapped with and connected to each other. Also, the negative-side second output part 28b protruding rearward from the third basic circuit unit 20c and the negative-side first output part 26b protruding forward from the first basic circuit unit 20a are overlapped with and connected to each other. In short, the second output part 28 of the third basic circuit unit 20c and the first output part 26 of the first basic circuit unit 20a are connected to each other. In all of the first to fourth basic circuit units 20a to 20d, the first output part 26 and the second output part 28 are thereby connected to each other. Note that, the shapes of the ends of the busbars 68b and 68j constituting the second output part 28 in the third basic circuit unit 20c and the shapes of the ends of the busbars 68b and 68j constituting the first output part 26 in the first basic circuit unit 20a are made different from each other so as to facilitate overlapping thereof.

### Terminal Block 76

In Embodiment 1, as shown in FIGS. 3 and 4 and FIG. 6, the second output part 28 of the third basic circuit unit 20c and the first output part 26 of the first basic circuit unit 20a are both held on a terminal block 76 and coupled together. That is, the power distribution device 10 is provided with the terminal block 76, and the terminal block 76 is disposed between the third basic circuit unit 20c and the first basic circuit unit 20a in the front-back direction. This terminal block 76 is made from a synthetic resin, for example, and has insulating properties.

The terminal block 76 has a pair of forward openings 78 and 78 into which the ends (positive-side second output part 28a and negative-side second output part 28b) of the busbars 68b and 68j protruding rearward from the third basic circuit unit 20c are respectively inserted. Also, the terminal block 76 has a pair of rearward openings 80 and 80 into which the ends (positive-side first output part 26a and negative-side first output part 26b) of the busbars 68b and 68j protruding forward from the first basic circuit unit 20a are respectively inserted. The positive-side first and second output parts 26a and 28a and the negative-side first and second output parts 26b and 28b inserted through the forward and rearward openings 78 and 80 are overlapped in a central portion of the terminal block 76 in the front-back direction and fixed to the terminal block 76 with bolts. The third basic circuit unit 20c (and fourth basic circuit unit 20d) and the first basic circuit unit 20a (and second basic circuit unit 20b) can thereby be electrically connected.

### Circuit Support Body 82

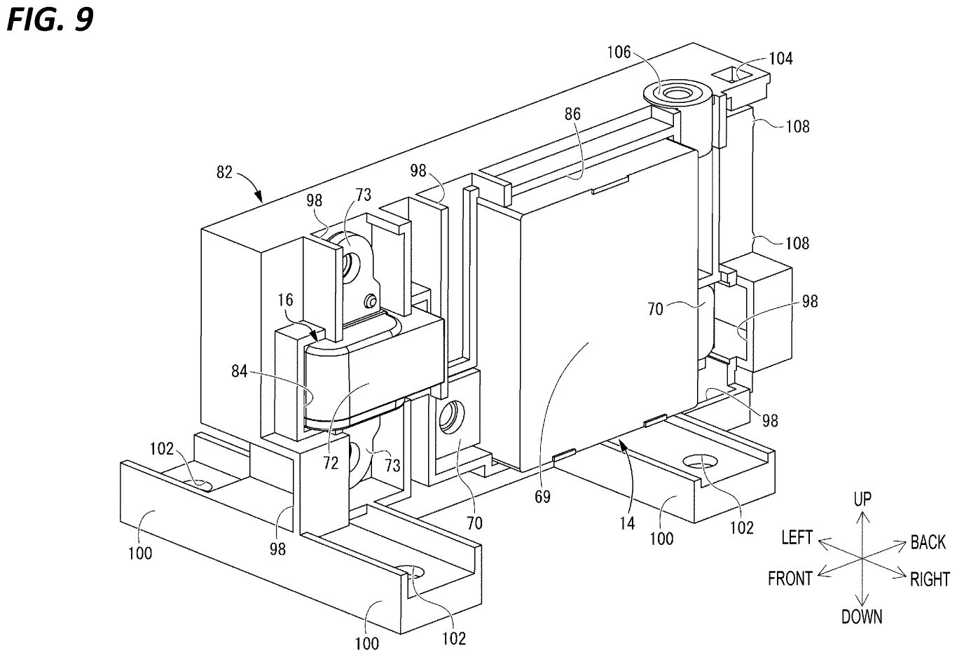

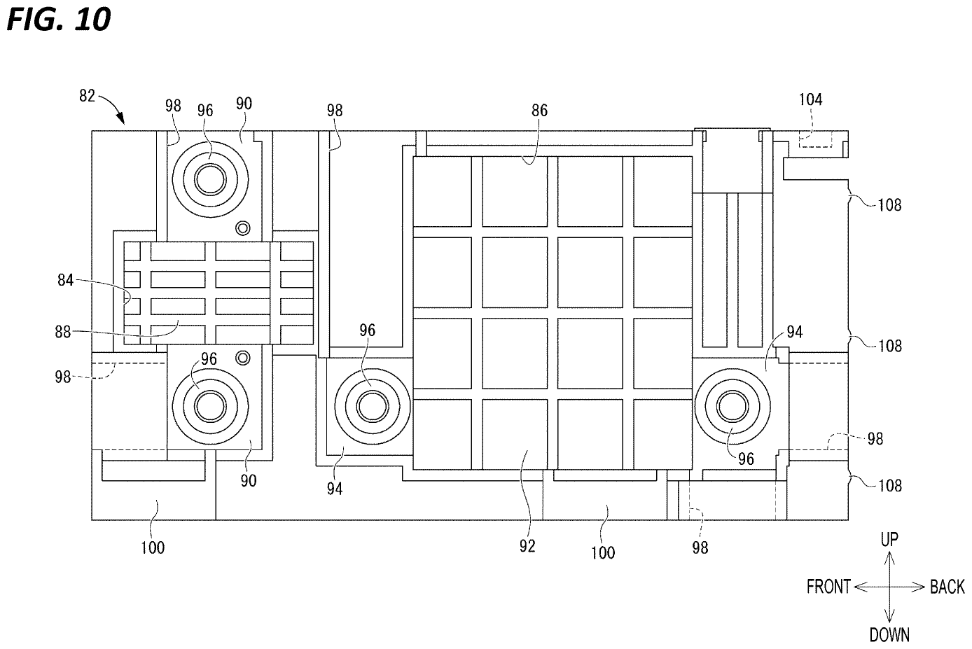

The basic circuit units 20a to 20d each include an insulating circuit support body 82. The shape of at least one of the circuit support bodies constituting the basic circuit units 20a to 20d may differ from the other circuit support bodies, but, in Embodiment 1, the circuit support bodies 82 constituting the basic circuit units 20a to 20d all have the same shape. The circuit support body 82 is shown in FIGS. 9 and 10, and, in particular, FIG. 9 shows the state in which the relay 14 and the current sensor 16 are attached to the circuit support body 82.

That is, the circuit support body 82 has a current sensor mounting part 84 on one end side (left end side in FIG. 10), and a relay mounting part 86 on the other end side (right end side in FIG. 10), and the current sensor 16 is mounted to the current sensor mounting part 84, and the relay 14 is mounted to the relay mounting part 86.

Specifically, the circuit support body 82 has a substantially rectangular plate shape as a whole and is made from a synthetic resin, for example. In the circuit support body 82, the current sensor mounting part 84 and the relay mounting part 86 are provided on both sides in the length direction (left-right direction in FIG. 10) on one surface in the thickness direction of the circuit support body 82 (surface on near side in FIG. 10). The current sensor mounting part 84 is constituted including a rectangular main body disposition area 88 in which the main body 72 of the current sensor 16 is disposed, and terminal disposition areas 90 and 90 provided on both sides (upper and lower sides in FIG. 10) of the main body disposition area 88 in which the terminals 73 are disposed. Also, the relay mounting part 86 is constituted by a rectangular main body disposition area 92 in which the main body 69 of the relay 14 is disposed, and terminal disposition areas 94 provided on both sides (left and right sides in FIG. 10) of the main body disposition area 92 in which the terminals 70 are disposed. A nut 96 is embedded in each of these terminal disposition areas 90 and 94.

Here, a plurality of openings 98 are provided in the outer peripheral edge of the circuit support body 82, and the internal spaces of the terminal disposition areas 90 constituting the current sensor mounting part 84 and the terminal disposition areas 94 constituting the relay mounting part 86 respectively communicate with the external space, through the openings 98. That is, the current sensor 16 and the relay 14 can be electrically connected to the busbars 68, by the ends of the busbars 68 being inserted into the circuit support body 82 through the openings 98, and the ends of the busbars 68 being overlapped with and bolt-fastened to the terminals 73 of the current sensor 16 and the terminals 70 of the relay 14.

Specifically, the circuit support body 82 is provided with two openings 98 that are open upward in FIG. 10, with one of the openings 98 communicating with the terminal disposition area 90 on the upper side in FIG. 10, and the other opening 98 communicating with the terminal disposition area 94 on the left side in FIG. 10. Also, the circuit support body 82 is provided with one each of openings 98 that are open leftward, downward, and rightward in FIG. 10, with the opening 98 that is open leftward in FIG. 10 communicating with the terminal disposition area 90 on the lower side in FIG. 10. Also, the openings 98 that are open downward and rightward in FIG. 10 both communicate with the terminal disposition area 94 on the right side in FIG. 10.

The shapes of the basic circuit units 20 constituted including the circuit support bodies 82 differ depending on the modes of insertion of the busbars 68 into such openings 98. In Embodiment 1, the first to fourth basic circuit units 20a to 20d are constituted, by the modes of insertion of the busbars 68 into the openings 98 being varied. Note that, given that the first and third basic circuit units 20a and 20c and the second and fourth basic circuit units 20b and 20d respectively have substantially the same shape, the basic circuit units 20 are substantively constituted by two types, namely, the first basic circuit unit 20a and the second basic circuit unit 20b.

In short, as shown in FIG. 7, in the first basic circuit unit 20a (and third basic circuit unit 20c), the busbar 68a having the input part 24 (first cathode-side input part 40a) at an end thereof is inserted through the upward opening 98 and overlapped with the front terminal 70 of the first relay 14a. Also, the busbar 68b having the first output part 26 (positive-side first output part 26a) and the second output part 28 (positive-side second output part 28a) at opposite ends thereof is disposed downward of the circuit support body 82, and the positive-side second output part 28a protruding upward is overlapped with the rear terminal 70 of the first relay 14a through the downward opening 98. Furthermore, the busbar 68h having the input part 24 (second anode-side input part 42b) at the one end thereof is disposed leftward of the circuit support body 82, and the other end thereof protruding downward is overlapped with the upper terminal 73 of the first current sensor 16 through the upward opening 98. The busbar 68i having the second output part 28 (negative-side second output part 28b) at the other end thereof is disposed leftward of the circuit support body 82, and the one end thereof bent rightward is overlapped with the lower terminal 73 of the first current sensor 16 through the forward opening 98. In particular, the one end of this busbar 68i is overlapped with the other end of the busbar 68j, and the ends of these busbars 68i and 68j are overlapped with the lower terminal 73 of the first current sensor 16 through the forward opening 98.

Also, as shown in FIG. 8, in the second basic circuit unit 20b (and fourth basic circuit unit 20d), the busbar 68c having the input part 24 (second cathode-side input part 42a) at an end thereof is inserted through the upward opening 98 and overlapped with the front terminal 70 of the second relay 14b. Also, the busbar 68d having the first output part 26 (positive-side first output part 26a) at the one end thereof is disposed downward of the circuit support body 82, and the other end thereof protruding upward is overlapped with the rear terminal 70 of the second relay 14b through the downward opening 98. The other end of this busbar 68d is overlapped with the one end of the busbar 68e having the positive-side second output part 28a at the other end thereof. Furthermore, the busbar 68f having the input part 24 (first anode-side input part 40b) at an end thereof is inserted through the upward opening 98 and overlapped with the upper terminal 73 of the second current sensor 16b. The busbar 68g having the first output part 26 (negative-side first output part 26b) and the second output part 28 (negative-side second output part 28b) at opposite ends thereof is disposed leftward of the circuit support body 82, and the one end (negative-side first output part 26b) thereof bent rightward is overlapped with the lower terminal 73 of the second current sensor 16b through the forward opening 98.

Accordingly, in Embodiment 1, the basic circuits 18 (first to fourth basic circuits 18a to 18d) are each constituted including a plurality of busbars 68 provided with one of the input part 24, the first output part 26, and the second output part 28 at an end thereof. Also, the first to fourth basic circuit units 20a to 20d are constituted, by these first to fourth basic circuits 18a to 18d being assembled to the circuit support bodies 82 having the same shape.

When the first basic circuit unit 20a and the second basic circuit unit 20b are connected, the negative-side second output part 28b protruding rearward in the first basic circuit unit 20a is inserted into the opening 98 that is open forward in the second basic circuit unit 20b, as shown in FIG. 4, and overlapped with the lower terminal 73 of the second current sensor 16b together with the negative-side first output part 26b of the second basic circuit unit 20b. The busbar 68i of the first basic circuit unit 20a is thereby connected to the busbar 68g of the second basic circuit unit 20b, and the busbar 68i of the first basic circuit unit 20a and the busbar 68i of the third basic circuit unit 20c are connected via the respective busbars 68j thereof. The anode-side connecting line 52b electrically connected along substantially the entire length in the length direction from the first basic circuit unit 20a to the fourth basic circuit unit 20d is thereby constituted by the busbars 68g, 68i, and 68j.

Also, the positive-side first output part 26a protruding forward and bent upward in the second basic circuit unit 20b is inserted into the opening 98 that is open downward in the first basic circuit unit 20a and overlapped with the rear terminal 70 of the first relay 14a together with the positive-side second output part 28a of the first basic circuit unit 20a. The busbar 68b of the first basic circuit unit 20a is thereby connected to the busbar 68d of the second basic circuit unit 20b, and the busbar 68b of the first basic circuit unit 20a is connected to the busbar 68b of the third basic circuit unit 20c. The cathode-side connecting line 52a electrically connected along the entire length in the length direction from the first basic circuit unit 20a to the fourth basic circuit unit 20d is thereby constituted by the busbars 68b and 68d.

In Embodiment 1, as shown in FIG. 9 and the like, the circuit support body 82 is provided with a leg 100 protruding outward in the thickness direction. This leg 100 is provided in a plurality of locations in each circuit support body 82, and, in Embodiment 1, the legs 100 and 100 protruding on both sides in the thickness direction of the circuit support body 82 are provided in the circuit support body 82 at a predetermined distance from each other in the front-back direction, with four legs 100 being provided in the circuit support body 82. A bolt insertion hole 102 is formed in each leg 100, and the basic circuit units 20a to 20d are fixed to a later-described casing 130 with bolts (not shown) inserted into the bolt insertion holes 102.

Also, in an upper end portion at one end (right end in FIG. 10) of the circuit support body 82 in the length direction, a positioning recess 104 for positioning the branch circuit unit 36 that is assembled in the basic circuit unit 20, and a nut 106 (not shown) to which a bolt (not shown) for bolt-fixing the branch circuit unit 36 to the basic circuit unit 20 is fastened are provided. In Embodiment 1, the positioning recess 104 is a bottomed recess that is open upward, and the nut 106 is embedded in the vicinity of the positioning recess 104.

Furthermore, in the circuit support body 82, a pressing protrusion 108 that protrudes outward in the length direction is provided on one end face (right end face in FIG. 10) in the length direction. This pressing protrusion 108 is provided along the entire length of the circuit support body 82 in the thickness direction and is formed in a plurality of locations (three locations in Embodiment 1) in the up-down direction. The protruding end face of each pressing protrusion 108 is constituted by a curved surface. These pressing protrusions 108 are provided between surfaces of the circuit support bodies 82 that oppose each other when connecting the first basic circuit unit 20a and the second basic circuit unit 20b, for example. As a result of the pressing protrusions 108 and the wall surface of the opposing circuit support body 82 elastically deforming when the pressing protrusions 108 come in contact with the wall surface of the opposing circuit support body 82, it becomes possible to absorb the tolerance between the first basic circuit unit 20a and the second basic circuit unit 20b, and to improve the holding force that holds the first basic circuit unit 20a and the second basic circuit unit 20b in the assembled state.

### Branch Circuit Unit 36

As shown in FIGS. 3, 4 and the like, the branch circuit unit 36 is connected to the second and fourth basic circuit units 20b and 20d which are at opposite ends in the length direction (front-back direction) when the first to fourth basic circuit units 20a to 20d are connected. The branch circuit units 36 connected to the second and fourth basic circuit units 20b and 20d have the same shape as each other and are disposed in a state of being rotated 180 degrees around a central axis extending in the up-down direction.

The branch circuit unit 36 is provided with the fuse 32 as aforementioned, and, in Embodiment 1, a pair of fuses 32 and 32 are supported on a fuse holder 110. The fuses 32 extend in the same direction as the length direction (front-back direction) of the first to fourth basic circuit units 20a to 20d, and each fuse 32 is provided with a main body 112 and a pair of terminals 114 and 114 that protrude from the main body 112 on both sides in the front-back direction. A bolt insertion hole 116 is formed in each terminal 114, and a nut 118 is embedded in the fuse holder 110 at a position corresponding to each bolt insertion hole 116.

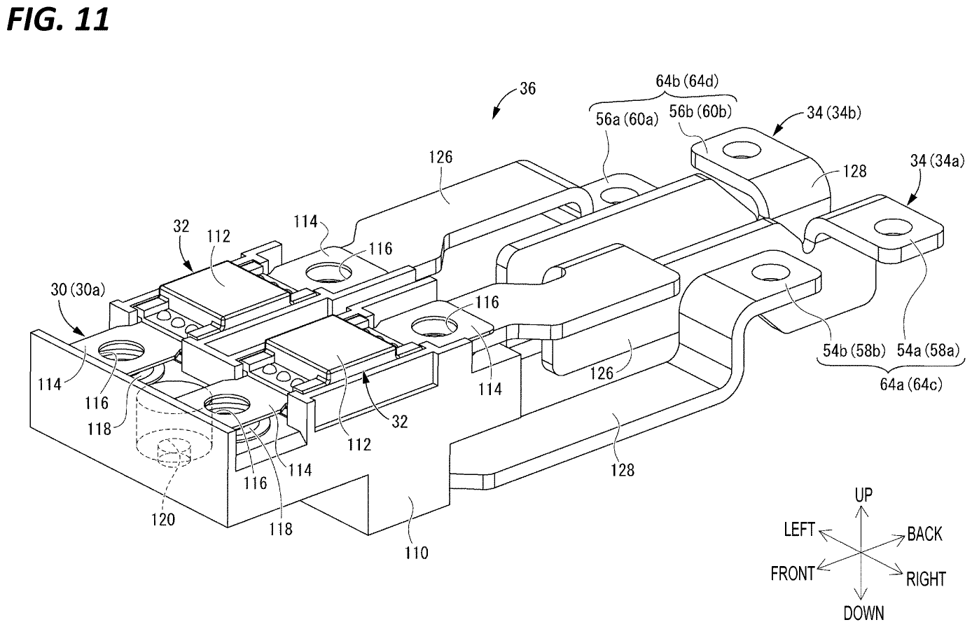

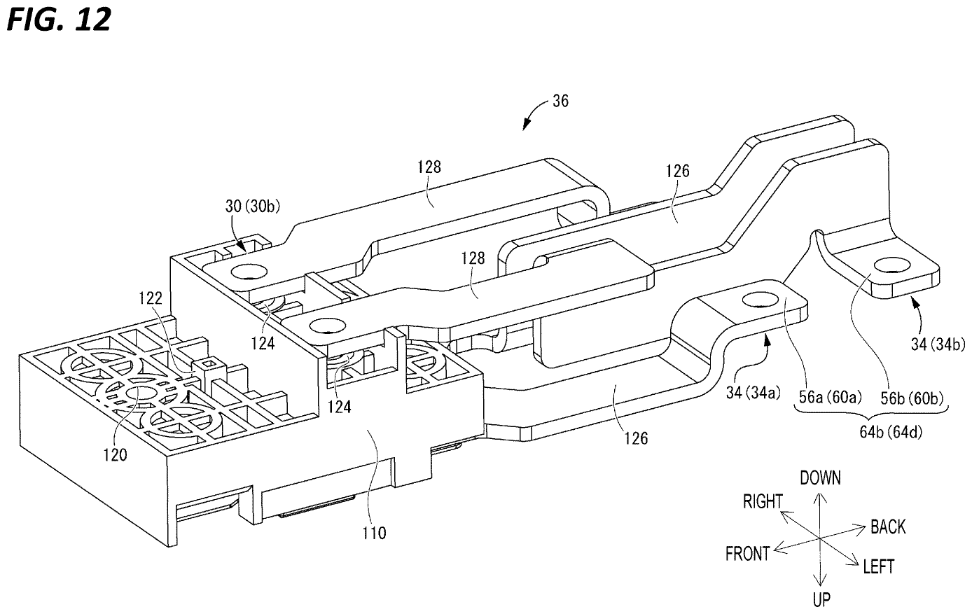

Also, between the left and right nuts 118 located on the forward side in FIG. 11, a bolt insertion hole 120 is formed that passes through the fuse holder 110 in the up-down direction. The branch circuit units 36 can be attached to the second and fourth basic circuit units 20b and 20d, by bolts (not shown) that are inserted into the bolt insertion holes 120 being fastened to the nuts 106 of the circuit support bodies 82 of the second and fourth basic circuit units 20b and 20d. Furthermore, on the lower surface of the fuse holder 110, a positioning projection 122 that fits into the positioning recess 104 is provided rearward of the bolt insertion hole 120 in FIG. 12. On the lower surface of the fuse holder 110, a pair of nuts 124 and 124 are provided in an embedded state rearward of the positioning projection 122 in FIG. 12.

With the fuses 32 placed on the fuse holder 110, a gap is formed in the up-down direction between the upper surface of the fuse holder 110 and the terminals 114 of the fuses 32. In the forward portion in FIG. 11, the positive-side second output part 28a (in fourth basic circuit unit 20d, positive-side first output part 26a) constituted by the other end of the busbar 68e of the second basic circuit unit 20b is inserted into the gap in the up-down direction between the upper surface of the fuse holder 110 and the terminals 114. The positive-side second output part 28a (or positive-side first output part 26a) is electrically connected to the fuses 32, by bolts (not shown) being inserted into the bolt insertion holes 116 in the terminals 114 and the bolt insertion holes 71 in the positive-side second output part 28a (or positive-side first output part 26a) and fastened to the nuts 118. Also, in the rearward portion in FIG. 11, one ends of a pair of positive-side end busbars 126 and 126 are inserted into the gap in the up-down direction between the upper surface of the fuse holder 110 and the terminals 114. The fuses 32 are electrically connected to the positive-side end busbars 126, by the terminals 114 being fixed to the positive-side end busbars 126 with bolts (not shown).

In Embodiment 1, the branch input part 30 (positive-side branch input part 30a) that is connected to the second output part 28 (positive-side second output part 28a) or the first output part 26 (positive-side first output part 26a) is thereby constituted by the terminals 114 of the fuses 32. Also, when the branch circuit unit 36 is connected to the second basic circuit unit 20b, the first cathode-side branch output part 54a is constituted by the other end of one (right side in FIG. 11) positive-side end busbar 126, and the second cathode-side branch output part 56a is constituted by the other end of the other (left side in FIG. 11) positive-side end busbar 126. When the branch circuit unit 36 is connected to the fourth basic circuit unit 20b, the third cathode-side branch output part 58a is constituted by the other end of the one positive-side end busbar 126, and the fourth cathode-side branch output part 60a is constituted by the other end of the other positive-side end busbar 126. Hence, in Embodiment 1, positive-side branch output parts 34a of the branch output parts 34 are constituted by the other ends of the positive-side end busbars 126.

Furthermore, the negative-side second output part 28b (in fourth basic circuit unit 20d, negative-side first output part 26b) constituted by the other end of the busbar 68g of the second basic circuit unit 20b is inserted from the left as shown in FIG. 12 with respect to the lower surface of the fuse holder 110 and overlapped therewith. As a result of one ends of a pair of negative-side end busbars 128 and 128 being overlapped with and fixed with bolts (not shown) to the negative-side second output part 28b (or negative-side first output part 26b), the negative-side second output part 28b (or negative-side first output part 26b) is electrically connected to the negative-side end busbars 128.

In Embodiment 1, the branch input part 30 (negative-side branch input part 30b) that is connected to the second output part 28 (negative-side second output part 28b) or the first output part 26 (negative-side first output part 26b) is thereby constituted by the one ends of the negative-side end busbars 128. Also, when the branch circuit unit 36 is connected to the second basic circuit unit 20b, the first anode-side branch output part 54b is constituted by the other end of one (right side in FIG. 11) negative-side end busbar 128, and the second anode-side branch output part 56b is constituted by the other end of the other (left side in FIG. 11) negative-side end busbar 128. When the branch circuit unit 36 is connected to the fourth basic circuit unit 20d, the third anode-side branch output part 58b is constituted by the other end of the one negative-side end busbar 128, and the fourth anode-side branch output part 60b is constituted by the other end of the other negative-side end busbar 128. Hence, in Embodiment 1, negative-side branch output parts 34b of the branch output parts 34 are constituted by the other ends of the negative-side end busbars 128.

### Casing 130

As shown in FIG. 1 to FIG. 3, the power distribution device 10 has the metal casing 130 that accommodates the basic circuit units 20a to 20d and the branch circuit units 36. The casing 130 is constituted including a substantially box-shaped casing main body 132 that is open upward and a substantially plate-shaped cover 134 that covers the upward opening of the casing main body 132, and after the upward opening of the casing main body 132 is covered by the cover 134, the casing main body 132 and the cover 134 can be fixed with bolts, for example. The casing main body 132 has a bottom wall 136 that has a long approximate rectangular shape in the front-back direction in plan view, and a peripheral wall 138 that protrudes upward from an outer peripheral edge of the bottom wall 136.

As aforementioned, given that the battery packs 12a to 12d are provided on both left and right sides with respect to the power distribution device 10, and respectively connected to the input parts 24 of the basic circuit units 20a to 20d, first to fourth through holes 140a to 140d are formed in the peripheral wall 138 of the casing main body 132 at positions corresponding to the input parts 24. The basic circuit units 20a to 20d are electrically connected to the battery packs 12a to 12d, by the terminals 22 of the battery packs 12a to 12d being respectively inserted inside the casing main body 132 through the through holes 140a to 140d, and the terminals 22 and the input parts 24 being bolt-fixed.

Also, a connector 142 is provided at positions in the peripheral wall 138 corresponding to the branch output parts 34. The connectors 142 are electrically connected to the first load-side branch output part 64a (first cathode-side and anode-side branch output part 54a and 54b), the second load-side branch output part 64b (second cathode-side and anode-side branch output parts 56a and 56b), the third load-side branch output part 64c (third cathode-side and anode-side branch output parts 58a and 58b), and the fourth load-side branch output part 64d (fourth cathode-side and anode-side branch output parts 60a and 60b). The loads 66a to 66d are electrically connected to the branch output parts 34, by connectors 144 of the loads 66a to 66d being connected to the connectors 142.

Furthermore, the busbars 68b and 68d connected to the relays 14a to 14d each have a heat dissipation contact part 148 that thermally contacts the casing 130 via a heat conduction sheet 146 that serves as an insulating member. Specifically, as shown in FIGS. 4 and 5, the busbars 68b and 68d connected to the relays 14a to 14d extend along substantially the entire length of the basic circuit units 20a to 20d in the length direction (front-back direction), downward of the basic circuit units 20a to 20d, and these busbars 68b and 68d thermally contact the bottom wall 136 of the casing 130 via the heat conduction sheet 146. The heat conduction sheet 146 is not limited as long as it has insulating properties and thermal conductivity, and a known heat conduction sheet can be employed. Here, the heat conduction sheet 146 is a rectangular sheet with a width dimension (dimension in left-right direction) larger than the individual busbars 68b and 68d, for example. Given that the positive-side first and second output parts 26a and 28a are constituted by the opposite ends of the busbars 68b and 68d in the front-back direction being bent upward, the heat dissipation contact part 148 that thermally contacts the bottom wall 136 via the heat conduction sheet 146 is constituted by an intermediate portion of the busbars 68b and 68d in the front-back direction.

### Method of Assembling Power Distribution Device 10

Hereinafter, a specific example of a method of assembling the power distribution device 10 will be described. Note that the method of assembling the power distribution device 10 is not limited to the following description.

First, the relay 14 and the current sensor 16 are respectively placed on the relay mounting part 86 and the current sensor mounting part 84 of the circuit support body 82. Also, the busbars 68a, 68b, 68h, 68i and 68j are inserted through the plurality of openings 98 in the circuit support body 82, and the ends of the busbars 68a and 68b and busbars 68h, 68i, and 68j are respectively overlapped with the terminals 70 of the relay 14 and the terminals 73 of the current sensor 16. Thereafter, the relay 14, the current sensor 16, and the busbars 68a, 68b, 68h, 68i, and 68j are fixed to the circuit support body 82 with bolts (not shown). The first basic circuit unit 20a and the third basic circuit unit 20c are thereby obtained.

Similarly, the relay 14 and the current sensor 16 are respectively placed on the relay mounting part 86 and the current sensor mounting part 84 of the circuit support body 82. Also, the busbars 68c, 68d, 68f, and 68g are inserted through the plurality of openings 98 in the circuit support body 82, and the ends of the busbars 68c and 68d and busbars 68f and 68g are respectively overlapped with the terminals 70 of the relay 14 and the terminals 73 of the current sensor 16. Furthermore, the busbar 68e is overlapped with the busbar 68d. Thereafter, the relay 14, the current sensor 16, and the busbars 68c, 68d, 68e, 68f, and 68g are fixed to the circuit support body 82 with bolts (not shown). The second basic circuit unit 20b and the fourth basic circuit unit 20d are thereby obtained.

Thereafter, the first basic circuit unit 20a and the second basic circuit unit 20b are coupled together. Specifically, as aforementioned, the end (negative-side second output part 28b) of the busbar 68i of the first basic circuit unit 20a is overlapped with the end (negative-side first output part 26b) of the busbar 68g of the second basic circuit unit 20b. Also, the end (positive-side first output part 26a) of the busbar 68d of the second basic circuit unit 20b is overlapped with the end (positive-side second output part 28a) of the busbar 68b of the first basic circuit unit 20a. The first basic circuit unit 20a and the second basic circuit unit 20b are coupled together, by bolt-fastening the overlapped busbars 68i and 68g and the overlapped busbars 68d and 68b. The third basic circuit unit 20c and the fourth basic circuit unit 20d are coupled together in a similar manner.

Next, the first basic circuit unit 20a and the third basic circuit unit 20c are coupled together. Specifically, as aforementioned, the ends (positive-side first output part 26a and positive-side second output part 28a) of the respective busbars 68b of the first basic circuit unit 20a and the third basic circuit unit 20c are overlapped on the terminal block 76, and the ends of the busbars 68b are fixed to the terminal block 76 with bolts (not shown). Similarly, the ends (negative-side first output part 26b and negative-side second output part 28b) of the respective busbars 68j of the first basic circuit unit 20a and the third basic circuit unit 20c are overlapped on the terminal block 76, and the ends of the busbars 68j are fixed to the terminal block 76 with bolts (not shown). The first to fourth basic circuit units 20a to 20d are thereby coupled together, by the first basic circuit unit 20a and the third basic circuit unit 20c being coupled together. In these first to fourth basic circuit units 20a to 20d, the heat conduction sheet 146 is adhered (e.g., bonded) to the busbars 68b and 68d extending in the front-back direction on the lower side.

Thereafter, the branch circuit units 36 are fixed to the ends of the second and fourth basic circuit units 20b and 20d on the outer side in the length direction (front-back direction). Specifically, the end (positive-side second output part 28a) of the busbar 68e of the second basic circuit unit 20b is overlapped with the fuses 32 and the positive-side end busbars 126 and fixed to the fuse holder 110 with bolts (not shown). Also, the end (negative-side second output part 28b) of the busbar 68g of the second basic circuit unit 20b is overlapped with the negative-side end busbars 128 and fixed to the fuse holder 110 with bolts (not shown). The branch circuit unit 36 is thereby coupled to the second basic circuit unit 20b. The branch circuit unit 36 is coupled to the fourth basic circuit unit 20d in a similar manner.

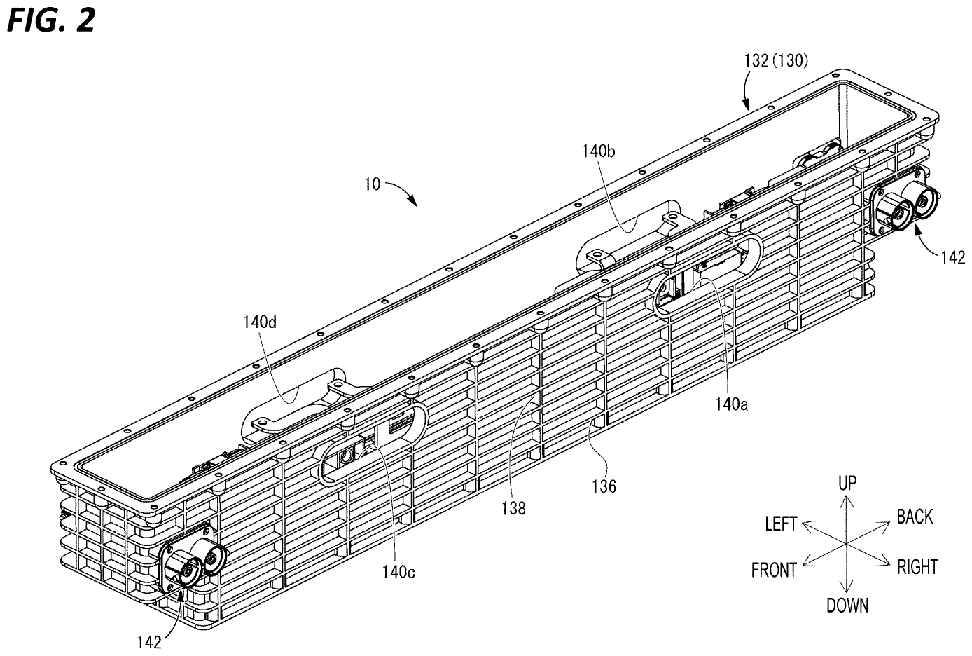

Next, the legs 100 of the circuit support bodies 82 of the basic circuit units 20a to 20d are bolt-fixed to the bottom wall 136, with the basic circuit units 20a to 20d and the branch circuit units 36 that are coupled together disposed within the casing main body 132, and the heat conduction sheet 146 overlapped with the bottom wall 136 of the casing main body 132. Also, the first to fourth load-side branch output parts 64a to 64d constituted by the positive-side and negative-side end busbars 126 and 128 in the branch circuit units 36 are bolt-fastened to the connectors 142 provided in the casing main body 132. The power distribution device 10 with the cover 134 removed as shown in FIG. 2 and FIG. 3 is thereby completed.

The first to fourth battery packs 12a to 12d are disposed on both left and right sides with respect to the power distribution device 10 assembled in this way, and the terminals 22 of the battery packs 12a to 12d are inserted through the through holes 140a to 140d provided in the casing main body 132. Thereafter, the power distribution device 10 is electrically connected the battery packs 12a to 12d, by the terminals 22 being bolt-fastened to the input parts 24 (first to fourth input parts 47a to 47d) of the basic circuit units 20a to 20d. The upward opening of the casing main body 132 is then covered by attaching the cover 134 to the casing main body 132, and the power distribution device 10 and the battery packs 12a to 12d are bolt-fixed onto the support plate 38. This support plate 38 is disposed in an appropriate location in the vehicle and fixed with bolts, for example, and power from the battery packs 12a to 12d is distributed to the loads 66a to 66d, by the connectors 144 of the loads 66a to 66d being connected to the connectors 142.

### Electrical Configuration of Power Distribution Device 10′

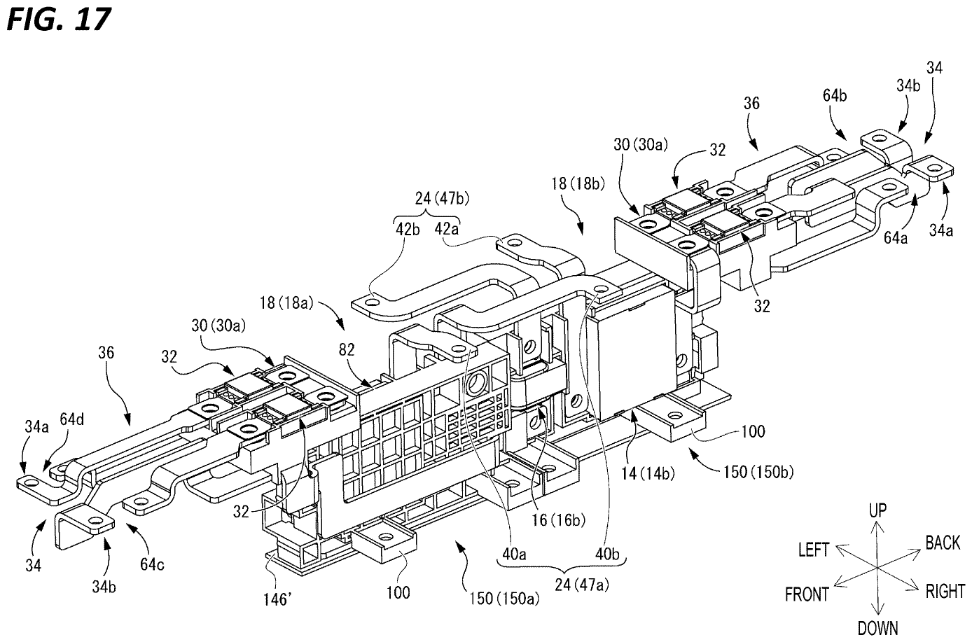

Next, the electrical configuration of the power distribution device 10′ will be described by showing FIG. 17 to FIG. 20. As aforementioned, in the power distribution device 10′ shown in FIG. 14 and the like, two battery packs 12 (first and second battery packs 12a and 12b) are connected, and two basic circuit units 150 (first and second basic circuit units 150a and 150b) are provided corresponding to the two battery packs 12a and 12b. As the basic circuit units 150 provided in the power distribution device 10′, the basic circuit unit on the front side is given as a first basic circuit unit 150a and the basic circuit unit on the rear side is given as a second basic circuit unit 150b.

The power distribution device 10′ is also provided with a first cathode-side input part 40a to which the cathode side of the first battery pack 12a is connected, and a first anode-side input part 40b to which the anode side of the first battery pack 12b is connected. Similarly, the power distribution device 10′ is provided with a second cathode-side input part 42a to which the cathode side of the second battery pack 12b is connected, and a second anode-side input part 42b to which the anode side of the second battery pack 12b is connected. A first input part 47a is constituted by the first cathode-side and anode-side input parts 40a and 40b, and a second input part 47b is constituted by the second cathode-side and anode-side input parts 42a and 42b.

First and second cathode-side lines 48a and 48b that respectively extend from the first and second cathode-side input parts 40a and 42a are connected in parallel to a cathode-side connecting line 52a, and the cathode-side connecting line 52a is branched into four downstream and constituted as first to fourth cathode-side branch output parts 54a, 56a, 58a, and 60a via fuses 32. These first and second cathode-side lines 48a and 48b are respectively connected to a first relay 14a and a second relay 14b.

Similarly, first and second anode-side lines 62a and 62b that respectively extend from the first and second anode-side input parts 40b and 42b are connected in parallel to an anode-side connecting line 52b, and the anode-side connecting line 52b is branched into four downstream and constituted as first to fourth anode-side branch output parts 54b, 56b, 58b, and 60b. A first current sensor 16a and a second current sensor 16b are respectively connected to these first and second anode-side lines 62a and 62b.

A first load 66a is connected to a first load-side branch output part 64a that is constituted by the first cathode-side and anode-side branch output parts 54a and 54b. Similarly, a second load 66b is connected to a second load-side branch output part 64b that is constituted by the second cathode-side and anode-side branch output parts 56a and 56b, a third load 66c is connected to a third load-side branch output part 64c that is constituted by the third cathode-side and anode-side branch output parts 58a and 58b, and a fourth load 66d is connected to a fourth load-side branch output part 64d that is constituted by the fourth cathode-side and anode-side branch output parts 60a and 60b. With such an electrical circuit configuration, in the power distribution device 10′ shown in FIG. 14 and the like, two battery packs 12a and 12b are connected in parallel, and power obtained from the battery packs 12a and 12b is distributed to the first to fourth loads 66a to 66d.

### Busbars 152a to 152f

In the aforementioned power distribution device 10, the first and second basic circuit units 20a and 20b and the third and fourth basic circuit units 20c and 20d respectively have substantially the same shape, with one thereof being rotated 180 degrees relative to the other thereof around a central axis extending in the up-down direction, whereas, with the power distribution device 10′, the first basic circuit unit 150a and the second basic circuit unit 150b are substantially the same shape, with one thereof being rotated 180 degrees relative to the other thereof around a central axis extending in the up-down direction. Accordingly, a second output part 28 of the second basic circuit unit 150b is constituted with the configuration of a first output part 26 of the first basic circuit unit 150a. Also, a first output part of the second basic circuit unit 150b is constituted with the configuration of a second output part of the first basic circuit unit 150a.

As shown in FIG. 17 to FIG. 19, the first basic circuit unit 150a includes a busbar 152a that is provided with the first cathode-side input part 40a connected to the first battery pack 12a and is electrically connected to the first relay 14a. The first cathode-side input part 40a serving as an input part 24 that is connected to a terminal 22 of the first battery pack 12a is constituted by one end of this busbar 152a. In the first basic circuit unit 150a, the one end (first cathode-side input part 40a) of the busbar 152a protrudes rightward toward the first relay 14a side. The other end of the busbar 152a is electrically connected to the first relay 14a, by being overlapped with and bolt-fastened to a terminal 70 that protrudes from a main body 69 of the first relay 14a. Similarly, the second basic circuit unit 150b has a busbar 152a that is provided with the second cathode-side input part 42a connected to the second battery pack 12b and is electrically connected to the second relay 14b.

Also, the first basic circuit unit 150a includes a busbar 152b that is connected to the downstream side of the first relay 14a. The busbar 152b extends in the up-down direction as a whole, with the other end (lower end) of the busbar 152b being overlapped with a front terminal 70 of the first relay 14a, and the first output part 26 (positive-side first output part 26a) being constituted by one end (upper end) of the busbar 152b. The one end (positive-side first output part 26a) of the busbar 152b is provided with two bolt insertion holes 71 and 71 similarly to the power distribution device 10, and a positive-side branch input part 30a that is constituted by terminals 114 and 114 of the fuses 32 in a branch circuit unit 36 is connected thereto. Similarly, the second basic circuit unit 150b includes a busbar 152b that is connected to the downstream side of the second relay 14b, and the positive-side branch input part 30a of the branch circuit unit 36 can be connected to the one end (positive-side first output part 26a) of the busbar 152b.

The downstream side of the first relay 14a and the downstream side of the second relay 14b are connected by a busbar 152c. That is, the busbar 152c is a busbar that constitutes the cathode-side connecting line 52a. The busbar 152c extends in the front-back direction as a whole, with one end (front end) of the busbar 152c protruding upward and being overlapped with the front terminal 70 of the first relay 14a together with the other end of the busbar 152b. Also, the other end (rear end) of a busbar 152d protrudes upward and is overlapped with the rear terminal 70 of the second relay 14b together with the other end of the busbar 152b.

In short, this busbar 152c is provided in common to the first and second basic circuit units 150a and 150b, and is located downward of the circuit support bodies 82 of the first and second basic circuit units 150a and 150b. The shape of the busbar 152c is rotationally symmetrical around a central axis extending in the up-down direction. Accordingly, the busbar 152c can be understood as a busbar that is integrally provided with a positive-side second output part that protrudes rearward from the first basic circuit unit 150a and a positive-side first output part that protrudes forward in the second basic circuit unit 150b, which is the first basic circuit unit 150a rotated 180 degrees around a central axis extending in the up-down direction. In the first basic circuit unit 150a and the second basic circuit unit 150b, the positive-side second output part and the positive-side first output part are thereby connected by the busbar 152c.

Also, the first basic circuit unit 150a includes a busbar 152d that is provided with the first anode-side input part 40b connected to the first battery pack 12a and is electrically connected to the first current sensor 16a. The first anode-side input part 40b serving as the input part 24 connected to the terminal 22 of the first battery pack 12a is constituted by one end of this busbar 152d. In the first basic circuit unit 20a, the one end (first anode-side input part 40b) of the busbar 152d protrudes rightward toward the first relay 14a side. The other end of the busbar 152d is electrically connected to the first current sensor 16a, by being overlapped with and bolt-fastened to a terminal 73 that protrudes from a main body 72 of the first current sensor 16a. Similarly, the second basic circuit unit 150b has a busbar 152d that is provided with the second anode-side input part 42b connected to the second battery pack 12b and is electrically connected to the second current sensor 16b.

A busbar 152e is connected to the downstream side of the first current sensor 16a. That is, the busbar 152e is provided in the first basic circuit unit 20a, and is a busbar that constitutes the anode-side connecting line 52b or is connected to the anode-side connecting line 52b. The busbar 152e extends in the front-back direction as a whole, with the other end (rear end) of the busbar 152e being overlapped with a terminal 73 that protrudes downward from the first current sensor 16a. Also, the negative-side first output part 26b is constituted by one end (front end) of the busbar 152e. The one end (negative-side first output part 26b) of the busbar 152e is provided with two bolt insertion holes 74 and 74 similarly to the power distribution device 10, and a negative-side branch input part 30b that is constituted by one ends of the negative-side end busbars 128 in the branch circuit unit 36 is connected thereto. Similarly, the second basic circuit unit 150b includes a busbar 152e whose other end is connected to the downstream side of the second current sensor 16b, and whose one end (negative-side first output part 26b) is connected to the branch circuit unit 36.

Here, the other ends of the busbars 152e of the first and second basic circuit units 150a and 150b are connected by a busbar 152f. The busbar 152f extends in the front-back direction as a whole, with the shape of the busbar 152f being rotationally symmetrical around a central axis extending in the up-down direction. One end (front end) of the busbar 152f is overlapped with the terminal 73 of the first current sensor 16a together with the other end of the busbar 152e, and the other end (rear end) of the busbar 152f is overlapped with a terminal 73 of the second current sensor 16b together with the other end of the busbar 152e.

In short, the busbar 152f can be understood as a busbar that is integrally provided with a negative-side second output part that protrudes rearward from the first basic circuit unit 150a and a negative-side first output part that protrudes forward in the second basic circuit unit 150b, which is the first basic circuit unit 150a rotated 180 degrees around a central axis extending in the up-down direction. In the first basic circuit unit 150a and the second basic circuit unit 150b, the negative-side second output part and the negative-side first output part are thereby connected by the busbar 152f.

### Basic Circuit Units 150 (First and Second Basic Circuit Units 150a, 150b)

From the above, as shown in FIG. 17 to FIG. 19, the first basic circuit unit 150a is provided with the first relay 14a and the first current sensor 16a, the busbars 152a and 152b connected to the first relay 14a, and the busbars 152d and 152e connected to the first current sensor 16a. As mentioned above, the second basic circuit unit 150b is the first basic circuit unit 150a rotated 180 degrees around a central axis extending in the up-down direction, and is provided with the second relay 14b and the second current sensor 16b, the busbars 152a and 152b connected to the second relay 14b, and the busbars 152d and 152e connected to the second current sensor 16b. Also, the first and second basic circuit units 150a and 150b are provided with the busbars 152c and 152f as common busbars.

In these first and second basic circuit units 150a and 150b, the relays 14a and 14b, the current sensors 16a and 16b, and the busbars 152a to 152f are assembled to the circuit support body 82 similarly to the aforementioned power distribution device 10. The assembly of the busbars 152a to 152f to the circuit support body 82 can be achieved through openings 98 as aforementioned, and, when connecting the first basic circuit units 150a and 150b, the opposite ends of the busbar 152f may be overlapped with the other ends of the busbars 152e through the openings 98.

Also, the branch circuit unit 36 is connected to opposite ends of the first and second basic circuit units 150a and 150b in the length direction, similarly to the aforementioned power distribution device 10. That is, the positive-side branch input part 30a of the branch circuit unit 36 is overlapped with and connected to the positive-side first output part 26a (or positive-side second output part 28a) constituted by the one end of the busbar 152b, and the negative-side branch input part 30b is overlapped with and connected the negative-side first output part 26b (or negative-side second output part 28b) constituted by the one end of the busbar 152e.

### Casing 130′

The shape of a casing 130′ of the power distribution device 10′ is a similar shape to the casing 130 of the aforementioned power distribution device 10. That is, the casing 130 of the aforementioned power distribution device 10 has a length dimension (dimension in front-back direction) that can accommodate four basic circuit units 20 (first to fourth basic circuit units 20a to 20d) and two branch circuit units 36, whereas the casing 130′ of the power distribution device 10′ has a length dimension that can accommodate two basic circuit units 150 (first and second basic circuit units 150a, 150b) and two branch circuit units 36. On both sides of a peripheral wall 138 of the casing 130′ in the left-right direction, first and second through holes 140a and 140b are respectively formed corresponding to the first and second battery packs 12a and 12b.

Also, in the power distribution device 10′, as shown in FIG. 17, a heat conduction sheet 146′ that serves as an insulating member is similarly adhered (e.g., bonded) to the busbar 152c connected to the relays 14a and 14b, and a heat dissipation contact part 154 of the busbar 152c thermally contacts a bottom wall 136 of the casing 130′ via the heat conduction sheet 146′. Given that the opposite ends of the busbar 152c in the front-back direction are bent upward and overlapped with the terminals 70 of the first and second relays 14a and 14b, the heat dissipation contact part 154 is constituted by an intermediate portion of the busbar 152c in the front-back direction.

### Method of Assembling Power Distribution Device 10′

The power distribution device 10′ can be assembled by a similar method to the aforementioned method of assembling the power distribution device 10.

That is, two units each obtained by assembling the relay 14, the current sensor 16, and the busbars 152a, 152b, 152d, and 152e to the circuit support body 82 are prepared, one of the units is rotated 180 degrees relative to the other unit around a central axis extending in the up-down direction, and the two units are connected by the busbars 152c and 152f. The first basic circuit unit 150a and the second basic circuit unit 150b are thereby connected in the front-back direction.

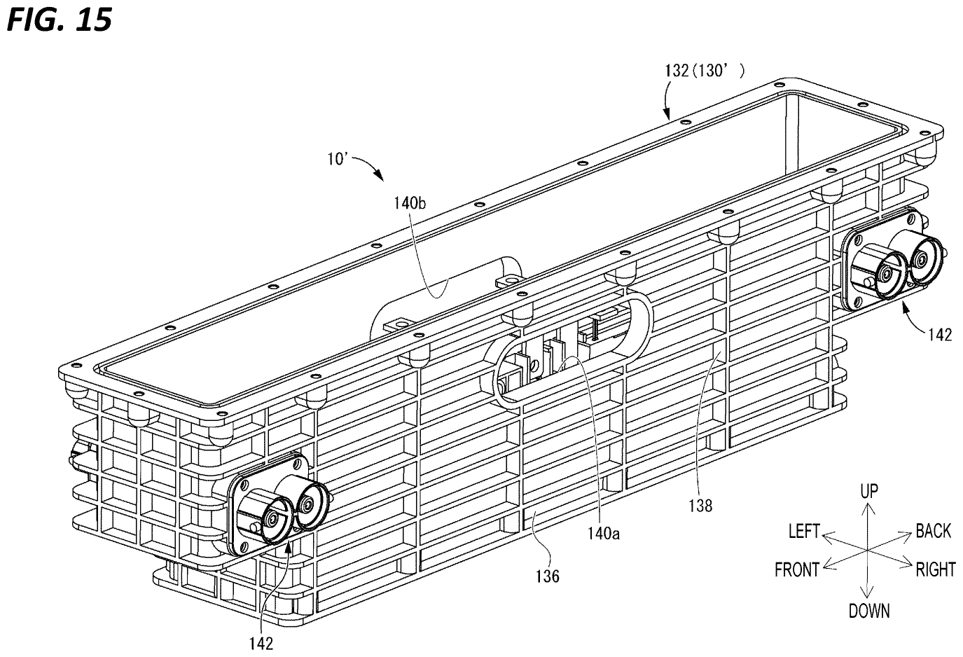

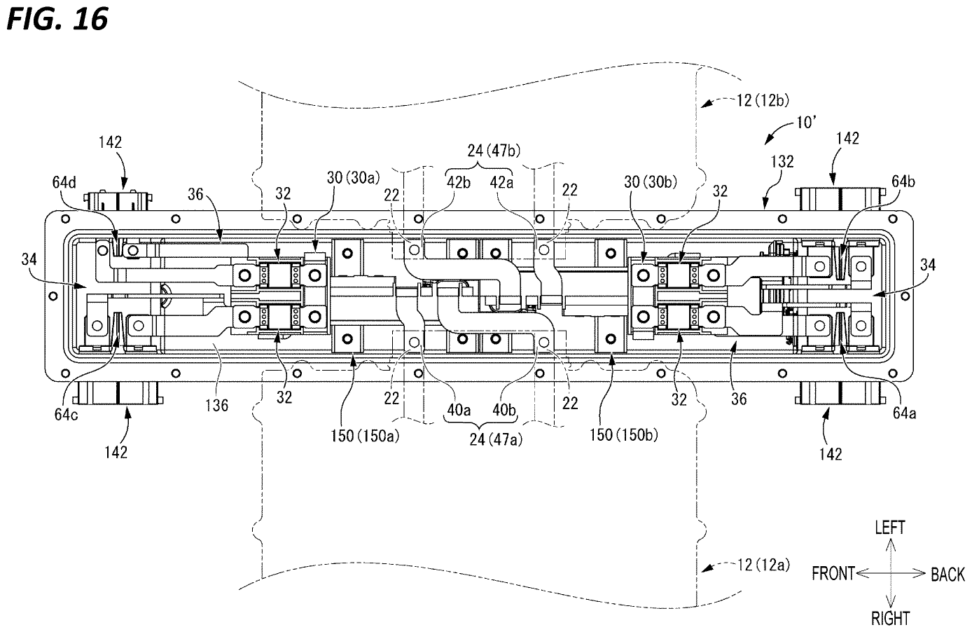

Also, the branch circuit unit 36 is connected to opposite ends of the first basic circuit unit 150a and the second basic circuit unit 150b in the front-back direction, and the heat conduction sheet 146′ is adhered (e.g., bonded) to the lower surface of the busbars 152c. Thereafter, the power distribution device 10′ without a cover 134 is completed, as shown in FIGS. 15 and 16, by accommodating and fixing the first and second basic circuit units 150a and 150b and the branch circuit units 36 in the casing 130′.

This power distribution device 10′ can be connected to two battery packs 12 (first and second battery packs 12a and 12b) and to connectors 144 of four loads (first to fourth loads 66a to 66d), similarly to the aforementioned power distribution device 10. Power from the battery packs 12a and 12b is thereby distributed to the loads 66a to 66.

With the power distribution devices 10 and 10′ of Embodiment 1 having a structure such as described above, in the case where the four battery packs 12a to 12d are used, for example, the power distribution device 10 in which the four basic circuit units 20a to 20d are coupled together can be employed, and in the case where the two battery packs 12a and 12b are used, the power distribution device 10′ in which the two basic circuit units 150a and 150b are coupled together can be employed. In this way, by adopting the structure of the present disclosure, it is possible to respond to an increase or decrease in the number of required battery packs 12 by increasing or decreasing the number of basic circuit units, and, in the case where the number of battery packs 12 provided is 2, 4, 6, and so on, for example, it is possible to respond by providing a corresponding number of basic circuit units such as 2, 4, 6 and so on. Power from the battery packs 12 can be distributed to a plurality of loads, by connecting branch circuit units at opposite ends of the basic circuit units.

In particular, in the power distribution device 10 shown in FIG. 1 and the like, the shapes of the first and second basic circuit units 20a and 20b and the third and fourth basic circuit units 20c and 20d are substantially rotationally symmetrical around a central axis extending in the up-down direction, and, in the power distribution device 10′ shown in FIG. 14 and the like, the shapes of the first basic circuit unit 150a and the second basic circuit unit 150b are substantially rotationally symmetrical around a central axis extending in the up-down direction. In the case of assembling either the power distribution device 10 or 10′, an excessive increase in the number of types of components is thereby avoided and improvement in assembly efficiency is achieved. Furthermore, given that units having the same shape as each other are also employed as the branch circuit units 36 provided at opposite ends, further improvement in assembly efficiency is achieved.

These basic circuit units 20a to 20d and 150a and 150b are all constituted including circuit support bodies 82 having the same shape as each other. That is, circuit support bodies 82 having the same shape can be employed regardless of the number of battery packs 12, and the desired basic circuit units, such as the first basic circuit unit 20a or 150a, the second basic circuit unit 20b, and the like, can be selectively manufactured, depending on the routing mode of the busbars to the circuit support body 82. An increase in the number of types of components is thereby further suppressed, and further improvement in manufacturing efficiency is achieved.

The power distribution device 10 has the casing 130 accommodating the basic circuit units 20a to 20d and the branch circuit units 36, and the power distribution device 10′ has the casing 130′ accommodating the basic circuit units 150a and 150b and the branch circuit units 36. Given that the basic structures of these casings 130 and 130′ are also the same as each other, and that the length dimension can be varied according to the number of basic circuit units, it becomes possible to manufacture the power distribution devices 10 and 10′, without major changes to the shapes of not only in the casings 130 and 130′ but also in the power distribution devices 10 and 10′. In particular, in the power distribution device 10, for example, the busbars 68b and 68d connected to the relays 14a and 14b are both located downward of the basic circuit units 20a to 20d, and are configured to thermally contact the bottom wall 136 of the casing 130 via a single heat conduction sheet 146. Heat generated in the relays 14a and 14b can thereby be dissipated with a simple structure. Also, given that a similar heat dissipation structure can be employed in any power distribution device in response to an increase or decrease in the number of basic circuit units, complicating the heat dissipation structure due to an increase in the number of basic circuit units, for example, can be avoided.

In the power distribution device 10, the first basic circuit unit 20a and the third basic circuit unit 20c are connected by the terminal block 76. The first and second basic circuit units 20a and 20b and the third and fourth basic circuit units 20c and 20d which respectively have the same shape as each other can thereby be coupled together. By employing such a terminal block, the number of basic circuit units can be easily increased, according to the number of battery packs.

### VARIATIONS

Embodiment 1 is described in detail above as a specific example of the present disclosure, but the present disclosure is not limited by this specific description. Modifications, improvements, and the like within a range that is able to achieve the object of the present disclosure are embraced in the present disclosure. For example, variations of the embodiment such as the following are also embraced in the technical scope of the present disclosure.
(1) In the embodiment, an example in which the number of battery packs 12 and basic circuit units 20 and 150 is two or four was shown, but the number of battery packs and basic circuit units is not limited thereto. For example, in the case where six battery packs are employed, a circuit for four battery packs such as the power distribution device 10 may be coupled in parallel to a circuit for two battery packs such as the power distribution device 10′, or three circuits for two battery packs such as the power distribution device 10′ may be coupled in parallel. That is, even in the case where four battery packs are provided, the routing mode of the busbars is not limited to that of the power distribution device 10 in the embodiment, and two circuits of the power distribution device 10′ may be provided in parallel. When coupling such circuits, the terminal block 76 described in the embodiment may be employed. Note that the number of battery packs does not necessarily have to match the number of basic circuit units, and the number of basic circuit units disposed need only corresponding to the number of battery packs, with the number of battery packs being proportional to the number of basic circuit units, for example.
(2) In the embodiment, four load-side branch output parts (first to fourth load-side branch output parts 64a to 64d) are provided such that the four loads 66a to 66d are connectable in the power distribution devices 10 and 10′, but the number of loads to be connected, that is, the number of load-side branch output parts, is not limited as long as there are more than one.
(3) In the embodiment, the first to fourth battery packs 12a to 12d are connected in parallel, but a configuration may be adopted in which a plurality of battery packs are connected in series by changing the routing mode of the busbars in the basic circuit units.
(4) In the embodiment, the connection between the first basic circuit units 20a and 150a and the second basic circuit units 20b and 150b, for example, is realized by the second output part 28 of the first basic circuit units 20a and 150a being connected to the first output part 26 of the second basic circuit units 20b and 150b. Note that a configuration may be adopted in which, at the time of connecting the first and second basic circuit units, the first and second basic circuit units are provisionally fixed to each other by providing protrusions and recesses in the opposing portions of the circuit support bodies of the first and second basic circuit units and mating the protrusions with the recesses.
(5) The voltage magnitude of the battery packs is not limited to 48 V, and battery packs of any voltage magnitude can be employed.

### LIST OF REFERENCE NUMERALS

10, 10′ Power distribution device
12 Battery pack
12a-12d First to fourth battery packs
14 Relay
14a-14d First to fourth relays
16 Current sensor
16a-16d First to fourth current sensors
18 Basic circuit
18a-18d First to fourth basic circuits
20 Basic circuit unit
20a-20d First to fourth basic circuit units
22 Terminal
24 Input part
26 First output part
26a Positive-side first output part
26b Negative-side first output part
28 Second output part
28a Positive-side first output part
28b Negative-side first output part
30 Branch input part
30a Positive-side branch input part
30b Negative-side branch input part
32 Fuse
34 Branch output part
34a Positive-side branch output part
34b Negative-side branch output part
36 Branch circuit unit
38, 38′ Support plates
40a, 42a, 44a, 46a First to fourth cathode-side input parts
40b, 42b, 44b, 46b First to fourth anode-side input parts
47a-47d First to fourth input parts
48a-48d First to fourth cathode-side lines
52a Cathode-side connecting line
52b Anode-side connecting line
54a, 56a, 58a, 60a First to fourth cathode-side branch output parts
54b, 56b, 58b, 60b First to fourth anode-side branch output parts
62a-62d First to fourth anode-side lines
64a-64d First to fourth load-side branch output parts
66a-66d First to fourth loads
68, 68a-68j Busbars
69 Main body
70 Terminal
71 Bolt insertion hole
72 Main body
73 Terminal
74 Bolt insertion hole
76 Terminal block
78 Forward opening
80 Rearward opening
82 Circuit support body
84 Current sensor mounting part
86 Relay mounting part
88 Main body disposition area
90 Terminal disposition area
92 Main body disposition area
94 Terminal disposition area
96 Nut
98 Opening
100 Leg
102 Bolt insertion hole
104 Positioning recess
106 Nut
108 Pressing protrusion
110 Fuse holder
112 Main body
114 Terminal
116 Bolt insertion hole
118 Nut
120 Bolt insertion hole
122 Positioning projection
124 Nut
126 Positive-side end busbar
128 Negative-side end busbar
130, 130′ Casing
132 Casing main body
134 Cover
136 Bottom wall
138 Peripheral wall
140a-140d First to fourth through holes
142, 144 Connector
146, 146′ Thermal conduction sheets (insulating members)
148 Heat dissipation contact part
150 Basic circuit unit
150a First basic circuit unit
150b Second basic circuit unit
152a-152f Busbars
154 Heat dissipation contact part

1. A power distribution device comprising:
a basic circuit unit including
a relay;
a current sensor; and
a basic circuit to which the relay and the current sensor are connected, the basic circuit having an input part connected to a terminal of a battery pack, a first output part, and a second output part; and
a branch circuit unit including
a branch input part connected to at least one of the first output part and the second output part of the basic circuit unit; and
a plurality of branch output parts each connected to the branch input part via a fuse,
wherein the basic circuit unit is disposed corresponding in number to how many of the battery pack are to be installed in a vehicle, and, in a case where a plurality of the basic circuit unit are employed corresponding to a plurality of the battery pack, the first output part of one of the basic circuit units adjacently disposed is coupled to the second output part of the other basic circuit unit adjacently disposed and the battery packs are conductively connected.

2. The power distribution device according to claim 1,
wherein the basic circuit unit includes an insulating circuit support body,
the current sensor is mounted to a current sensor mounting part provided at one end side of the circuit support body, and the relay is mounted to a relay mounting part provided at the other end side of the circuit support body, and
the basic circuit is constituted including a plurality of busbars each provided with one of the input part, the first output part, and the second output part at an end thereof, and is assembled to the circuit support body.

3. The power distribution device according to claim 2, further comprising:
a metal casing accommodating the basic circuit unit and the branch circuit unit,
wherein the busbars connected to the relay have a contact part for heat dissipation that thermally contacts the casing via an insulating member.

4. The power distribution device according to claim 2, further comprising:
an insulating terminal block disposed between the circuit support bodies of the basic circuit units adjacently disposed,
wherein one of the basic circuit units and the other basic circuit unit are held and coupled together in the terminal block.
